(19) United States
(12) Patent Application Publication
(10) Pub. No.: US 2025/0384931 A1
(43) Pub. Date: Dec. 18, 2025

(54) MEMORY DEVICE AND OPERATING METHOD THEREOF

(71) Applicant: SAMSUNG ELECTRONICS CO., LTD., Suwon-si (KR)

(72) Inventors: Young Hwi YANG, Suwon-si (KR); Kwang Ho CHOI, Suwon-si (KR)

(73) Assignee: SAMSUNG ELECTRONICS CO., LTD., Suwon-si (KR)

(21) Appl. No.: 19/009,613

(22) Filed: Jan. 3, 2025

(30) Foreign Application Priority Data
Jun. 18, 2024 (KR) 10-2024-0078616

(51) Int. Cl. G11C 16/10; G11C 16/04; G11C 16/08; G11C 16/24; G11C 16/30

(52) U.S. Cl. CPC G11C 16/10; G11C 16/0483; G11C 16/08; G11C 16/24; G11C 16/30

(57) ABSTRACT

A memory device includes a memory cell array including a plurality of memory cells coupled with a plurality of word lines and a plurality of bit lines, a row decoder circuit configured to select at least one of the plurality of word lines, a voltage generation circuit, a page buffer circuit coupled with the plurality of bit lines, and a control logic circuit configured to control the row decoder circuit, the voltage generation circuit, and the page buffer circuit. The voltage generation circuit is configured to provide a first word line voltage to a selected word line and a second word line voltage to an unselected word line. The page buffer is configured to receive first data to be programmed in the plurality of memory cells, provide a first bit line voltage to a selected bit line, and provide a second bit line voltage to an unselected bit line.

### CROSS-REFERENCE TO RELATED APPLICATIONS

This application claims benefit of priority under 35 U.S.C. § 119 to Korean Patent Application No. 10-2024-0078616, filed on Jun. 18, 2024, in the Korean Intellectual Property Office, the disclosure of which is incorporated by reference herein in its entirety.

### BACKGROUND

### 1. Field

The present disclosure relates generally to semiconductor devices, and more particularly, to a memory device and an operating method thereof.

### 2. Description of Related Art

A memory device may refer to a semiconductor device that may be used to store data. Memory devices may be classified, for example, into a volatile memory device and/or a nonvolatile memory device. A volatile memory device may refer to a memory device that may lose stored data when a power supply is cut off, and a nonvolatile memory device may refer to a memory device that may retain stored data when the power supply is cut off. As a non-limiting example of a nonvolatile memory device, a flash memory device may be used in a mobile device, such as, but not limited to, a mobile phone, a cellular phone, a smartphone, a digital camera, a personal digital assistant (PDA), a computer device, a table computer, a laptop computer, or the like. Such a nonvolatile memory device may need to provide a minimum level of reliability regardless of a position at which data is stored within the nonvolatile memory device.

### SUMMARY

Aspects of the present disclosure provide a memory device in which reliability of a threshold voltage distribution of a memory cell is improved, by removing a deeply erased memory cell, when compared to a related memory device.

Additional aspects of the present disclosure provide a method for operating a memory device in which reliability of a threshold voltage distribution of a memory cell is improved, by removing a deeply erased memory cell, when compared to a related memory device.

However, aspects of the present disclosure are not restricted to the embodiments set forth herein. The above and other aspects of the present disclosure are to be more apparent to one of ordinary skill in the art to which the present disclosure pertains by referencing the detailed explanation of the present disclosure given below.

According to an aspect of the present disclosure, a memory device includes a memory cell array, a row decoder circuit, a voltage generation circuit, a page buffer circuit, and a control logic circuit. The memory cell array includes a plurality of memory cells coupled with a plurality of word lines and a plurality of bit lines. The row decoder circuit is configured to select at least one of the plurality of word lines based on a row address. The voltage generation circuit is configured to provide a first word line voltage to a selected word line from among the plurality of word lines, and to provide a second word line voltage to an unselected word line from among the plurality of word lines. The page buffer circuit is coupled with the plurality of bit lines, and is configured to receive first data to be programmed in the plurality of memory cells, to provide a first bit line voltage to a selected bit line from among the plurality of bit lines, and to provide a second bit line voltage to an unselected bit line from among the plurality of bit lines. The control logic circuit is configured to control the row decoder circuit, the voltage generation circuit, and the page buffer circuit. The second bit line voltage is greater than the first bit line voltage. The plurality of word lines includes a first word line and a second word line that are sequentially selected by the row decoder circuit. The plurality of memory cells includes a first memory cell coupled with the first word line, and a second memory cell coupled with the second word line. The first memory cell and the second memory cell share a first bit line. The control logic circuit is further configured to apply the first bit line voltage to the first bit line, based on second data to be programmed in the first memory cell being in a lower status, and to apply a first program voltage to the second word line, while applying the first bit line voltage to the first bit line.

According to an aspect of the present disclosure, a memory device includes a memory cell array, a row decoder circuit, a voltage generation circuit, a page buffer circuit, and a control logic circuit. The memory cell array includes a plurality of memory cells coupled with a plurality of word lines and a plurality of bit lines. The row decoder circuit is configured to select at least one of the plurality of word lines based on a row address. The voltage generation circuit is configured to provide a first word line voltage to a selected word line from among the plurality of word lines, and to provide a second word line voltage to an unselected word line from among the plurality of word lines. The page buffer circuit is coupled with the plurality of bit lines, and is configured to receive first data to be programmed in the plurality of memory cells, to provide a first bit line voltage to a selected bit line from among the plurality of bit lines, and to provide a second bit line voltage to an unselected bit line from among the plurality of bit lines. The control logic circuit is configured to control the row decoder circuit, the voltage generation circuit, and the page buffer circuit. The second bit line voltage is greater than the first bit line voltage. The plurality of word lines includes a first word line, a second word line and a third word line that are sequentially selected by the row decoder circuit. The plurality of memory cells includes a first memory cell coupled with the first word line, a second memory cell coupled with the second word line, and a third memory cell coupled with the third word line. The first memory cell, the second memory cell, and the third memory cell share a first bit line. The control logic circuit is further configured to apply the first bit line voltage to the first bit line based on second data to be programmed in the second memory cell being in a lower status, and to apply a first program voltage to the third word line while applying the first bit line voltage to the first bit line. The second data to be programmed in the second memory cell is programmed into the second memory cell after the control logic circuit performs a primary program operation.

According to an aspect of the present disclosure, a method for operating a memory device includes receiving, from a memory controller, a program command, selecting, by a row decoder circuit of the memory device, a first word line from among a plurality of word lines, receiving, from the memory controller, first data to be programmed into a first memory cell coupled with the first word line, applying, by a control logic circuit of the memory device, a first voltage to a first bit line coupled with the first memory cell based on the first data to be programmed in the first memory cell being in a lower status, and applying, by the control logic circuit, a first program voltage to a second word line to be selected by the row decoder circuit following the first word line by the control logic circuit, in a first state in which the first voltage is applied to the first bit line during a first time interval.

It is to be noted that the effects of the present disclosure are not limited to those described above, and other effects of the present disclosure are to be apparent from the following description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 is a diagram of a storage system, according to some embodiments;

FIG. 2 is a diagram of a storage device, according to some embodiments;

FIG. 3 is a diagram of a storage device, according to some embodiments;

FIG. 4 is a diagram of a storage device, according to some embodiments;

FIG. 5 is a diagram of a memory device, according to some embodiments;

FIG. 6 is a diagram showing an example of the memory cell array of FIG. 5, according to some embodiments;

FIG. 7 is a diagram of an example of the memory block of FIG. 5, according to some embodiments;

FIG. 8 is a diagram of the program operation and the soft program operation on the memory block of FIG. 7, according to some embodiments;

FIG. 9 is a diagram showing an example of a threshold voltage distribution of the memory cells when data is programmed to the memory cells connected to any one of the word lines of FIG. 8, according to some embodiments;

FIG. 10 is a flowchart of the operation of the storage device, according to some embodiments;

FIG. 11 is a flowchart of the operation of the memory device, according to some embodiments;

FIG. 12 is a diagram showing the threshold voltage distribution of the memory cells before the program operation is performed on the memory cells connected to the selected word line and the memory cells connected to the adjacent word line, according to some embodiments;

FIG. 13 is a diagram showing the threshold voltage distribution of the memory cells, after the program operation on the memory cells connected to the selected word line is completed and before the program operation on the memory cells connected to the adjacent word line is performed, according to some embodiments;

FIG. 14 is a diagram showing the threshold voltage distribution of the memory cells when a soft program operation is performed on the memory cells connected to the adjacent word line before the program operation is performed on the memory cells connected to the selected word line, according to some embodiments;

FIG. 15 is a diagram showing the threshold voltage distribution of the memory cells after the program operation on the memory cells connected to the selected word line is completed and before the program operation on the memory cells connected to the adjacent word line subjected to the soft program operation is performed, according to some embodiments;

FIG. 16 is a diagram showing the threshold voltage distribution of the memory cells when the program operation on the memory cells connected to the selected word line is completed and the program operation is performed on the memory cells connected to the adjacent word line in which the soft program operation is completed, according to some embodiments;

FIG. 17 is a diagram of a program operation of a memory device according to the method of FIG. 10, according to some embodiments;

FIG. 18 is a flowchart of the operation of the storage device, according to some embodiments;

FIG. 19 is a flowchart of an operation of a memory device, according to some embodiments;

FIG. 20 is a diagram of the program operation of the memory device according to the method of FIG. 19, according to some embodiments;

FIG. 21 is a flowchart of the operation of the memory device, according to some embodiments;

FIGS. 22 to 27 are diagrams of the program operation on the memory cells connected to the selected word line and the soft program operation on the memory cells connected to adjacent word lines of the memory device, according to some embodiments;

FIG. 28 is a diagram showing the threshold voltage distribution of the memory cells when the program operation on the memory cells is performed according to the method of FIG. 21, according to some embodiments;

FIG. 29 is a diagram of a computing system including the storage device, according to some embodiments;

FIG. 30 is a diagram showing an example in which the storage device is applied to solid-state drive (SSD) system, according to some embodiments; and

FIG. 31 is a diagram of a system including the memory device, according to some embodiments.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1 st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

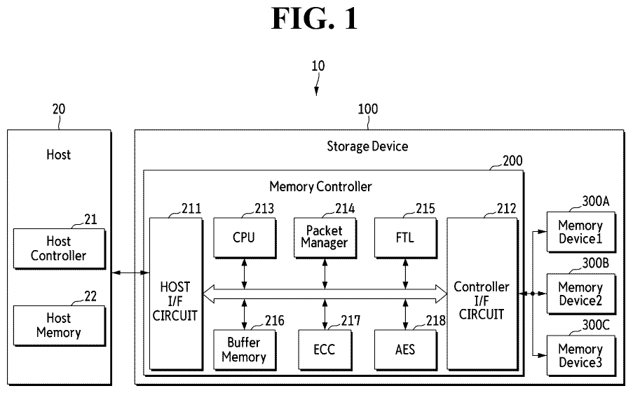

FIG. 1 is a diagram of a storage system, according to some embodiments.

The storage system 10 may include a host 20 and a storage device 100. The storage device 100 may also include a memory controller 200 and a plurality of memory devices (e.g., a first memory device 300A, a second memory device 300B, and a third memory device 300C, hereinafter generally referred to as 300). The host 20 may include a host controller 21 and a host memory 22. The host memory 22 may function as a buffer memory for temporarily storing data to be transmitted to the storage device 100 and/or data transmitted from the storage device 100.

The storage device 100 may be and/or may include a storage medium for storing data in accordance with a request from the host 20. As an example, the storage device 100 may include, but not be limited to, at least one of a solid-state drive (SSD), an embedded memory, a detachable external memory, or the like. When the storage device 100 is and/or includes an SSD, the storage device 100 may be and/or may include a device that complies with Nonvolatile Memory express (NVMe) standard. When the storage device 100 is and/or includes an embedded memory and/or an external memory, the storage device 100 may be and/or include a device that complies with a universal flash storage (UFS) and/or embedded multi-media card (eMMC) standard. However, the present disclosure is not limited in this regard, and the storage device 100 may be and/or may include devices that may comply with other storage and/or telecommunication standards. The host 20 and the storage device 100 may generate and/or transmit packets according to an adopted standard protocol.

Each of the plurality of memory devices 300 of the storage device 100 may include a flash memory. For example, the flash memory may be and/or may include a two-dimensional (2D) NAND memory array and/or a three-dimensional (3D) (or vertical) NAND (VNAND) memory array. As another example, the storage device 100 may include different various types of nonvolatile memories. For example, the storage device 100 may include, but not be limited to, a magnetic random-access memory (MRAM), a spin-transfer torque MRAM, a conductive-bridging random-access memory (CBRAM), a ferroelectric random-access memory (FeRAM), a phase random-access memory (PRAM), a resistive random-access memory (RRAM), and various other types of memories may be adopted as the storage device 100. In the following description, a case where each of the plurality of memory devices 300 is a NAND flash memory is described as an example.

The host controller 21 and the host memory 22 may be implemented by separate semiconductor chips. Alternatively or additionally, the host controller 21 and the host memory 22 may be integrated on the same semiconductor chip. The host controller 21 may be any one of a plurality of modules provided in the application processor, and the application processor may be implemented as a system on chip (SoC). Further, the host memory 22 may be an embedded memory provided inside the application processor, and/or a nonvolatile memory or a memory module placed outside the application processor.

The host controller 21 may manage an operation of storing the data (e.g., write data) of the host memory 22 in the plurality of memory devices 300 or storing the data (for example, read data) of the plurality of memory devices 300 in the host memory 22.

The memory controller 200 may include a host interface (I/F) circuit 211, a controller interface (I/F) circuit 212, and a central processing unit (CPU) 213. In addition, the memory controller 200 may further include a flash translation layer (FTL) 215, a packet manager 214, a buffer memory 216, an error correction code (ECC) 217 engine, and an advanced encryption standard (AES) 218 engine. The memory controller 200 may further include a working memory into which the FTL 215 is loaded, and when the CPU 213 executes the FTL 215, the data write and read operations on the plurality of memory devices 300 may be controlled.

The host interface circuit 211 may transmit and/or receive packets to and/or from the host 20. The packets transmitted from the host 20 to the host interface circuit 211 may include, but not be limited to, a command, data to be written in the plurality of memory devices 300, or the like. The packets transmitted from the host interface circuit 211 to the host 20 may include, but not be limited to, a response to the command, data that are read from the plurality of memory devices 300, or the like. The controller interface circuit 212 may transmit the data to be written in the plurality of memory devices 300 to the plurality of memory devices 300 and/or may receive the data that are read from the plurality of memory devices 300. Such a controller interface circuit 212 may be implemented to comply with standard protocols such as, but not be limited to, Toggle, open NAND flash interface (ONFI), or the like.

The FTL 215 may perform various functions such as, but not limited to, address mapping, wear-leveling, garbage collection, or the like. The address mapping operation may refer to an operation of changing a logical address received from the host 20 into a physical address which may be used for actually storing the data in the plurality of memory devices 300. The wear-leveling operation may refer to a technique for ensuring that blocks in the plurality of memory devices 300 are used uniformly to potentially prevent an excessive degradation of a particular block, and may be implemented, for example, through a firmware technique for balancing the erasure counts of the physical blocks. The garbage collection operation may refer to a technique for ensuring an available capacity in the plurality of memory devices 300 through a method of copying the valid data of the block to a new block and then erasing the existing block.

The packet manager 214 may, for example, generate a packet according to a standard interface protocol (e.g., as discussed above with reference to the host 20), or may parse various types of information from the packet received from the host 20. Further, the buffer memory 216 may temporarily store the data to be written in the plurality of memory devices 300 and/or the data to be read from the plurality of memory devices 300. The buffer memory 216 may be configured to be provided inside the memory controller 200. Alternatively or additionally, the buffer memory 216 may be disposed outside the memory controller 200.

The ECC engine 217 may perform error detection and correction functions on the read data that are read from the plurality of memory devices 300. In particular, the ECC engine 217 may generate parity bits for the write data to be written on the plurality of memory devices 300, and the parity bits thus generated may be stored in the plurality of memory devices 300 together with the write data. When reading the data from the plurality of memory devices 300, the ECC engine 217 may correct errors of the read data, using the parity bits that are read from the plurality of memory devices 300, together with the read data, and may output the read data with corrected errors.

The AES engine 218 may perform at least one of an encryption operation and a decryption operation on the data which is input to the memory controller 200, using a symmetric-key algorithm, for example. However, the present disclosure is not limited in this regard, and the AES engine 218 may perform encryption and/or decryption operations using other algorithms.

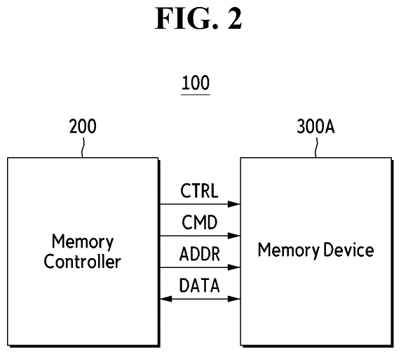

FIG. 2 is a diagram of a storage device, according to some embodiments.

Referring to FIG. 2, the storage device 100 may include a memory controller 200 and a first memory device 300A. Although FIG. 2 exemplarily shows the first memory device 300A from among the plurality of memory devices 300 included in the storage system 10 of FIG. 1, the present disclosure is not limited in this regard, and the storage device 100 may include the plurality of memory devices 300 as described above with reference to FIG. 1. Hereinafter, the description of the first memory device 300A may also be similarly applied to the other memory devices of the plurality of memory devices 300 (e.g., the second memory device 300B and the third memory device 300C).

The memory controller 200 may perform a control operation on the first memory device 300A. In particular, the memory controller 200 may generate an address ADDR, a command CMD, and/or a control signal CTRL for controlling the first memory device 300A. The memory controller 200 may control program (or write), read, and erase operations on the first memory device 300A by providing the address ADDR, the command CMD, and the control signal CTRL to the first memory device 300A. In addition, data DATA for the program operation and the read data DATA may be transmitted and/or received between the memory controller 200 and the first memory device 300A.

In some embodiments, the memory controller 200 may generate the control signal CTRL, the command CMD, the address ADDR, and the data DATA for performing a soft program operation on the first memory device 300A. In addition, the memory controller 200 may transmit the control signal CTRL, the command CMD, the address ADDR, and the data DATA generated for performing the soft program operation on the first memory device 300A to the first memory device 300A.

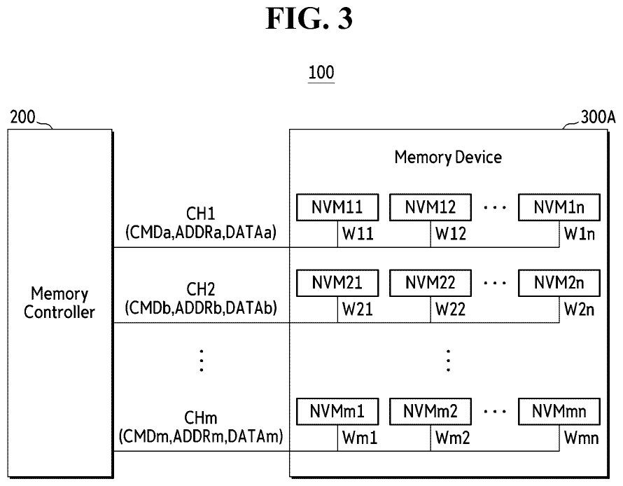

FIG. 3 is a diagram of a storage device, according to some embodiments.

Referring to FIG. 3, the first memory device 300A and the memory controller 200 may be connected through a plurality of channels (e.g., a first channel CH1, a second channel CH2, to an m-th channel CHm, where m is a positive integer greater than one (1)).

The first memory device 300A may include a plurality of nonvolatile memory devices NVM11 to NVMmn (where n is a positive integer greater than one (1)). Each of the plurality of nonvolatile memory devices NVM11 to NVMmn may be connected to one of the plurality of channels CH1 to CHm through a corresponding manner. In an embodiment, each of the nonvolatile memory devices NVM11 to NVMmn may be implemented as a memory unit capable of operating according to individual commands from the memory controller 200. For example, each of the nonvolatile memory devices NVM11 to NVMmn may be implemented as a chip or a die. However, the present disclosure is not limited thereto.

The memory controller 200 may transmit and/or receive signals to and/or from the first memory device 300A through the plurality of channels CH1 to CHm. For example, the memory controller 200 may respectively transmit commands CMDa to CMDm, addresses ADDRa to ADDRm, and data DATAa to DATAm to the first memory device 300A through the channels CH1 to CHm, and/or may respectively receive the data DATAa to DATAm from the first memory device 300A through the channels CH1 to CHm.

The memory controller 200 may select one of the nonvolatile memory devices connected to the channel through each channel, and transmit and/or receive signals to and/or from the selected nonvolatile memory device.

The memory controller 200 may transmit and/or receive signals in parallel to and/or from the first memory device 300A through different channels from each other. For example, the memory controller 200 may transmit a command CMDb to the nonvolatile memory device NVM21 through the second channel CH2, while transmitting a command CMDa to the nonvolatile memory device NVM11 through the first channel CH1. In such an example, the memory controller 200 may receive the data DATAb from the memory device NVM21 through the second channel CH2, while receiving the data DATAa from the memory device NVM11 through the first channel CH1.

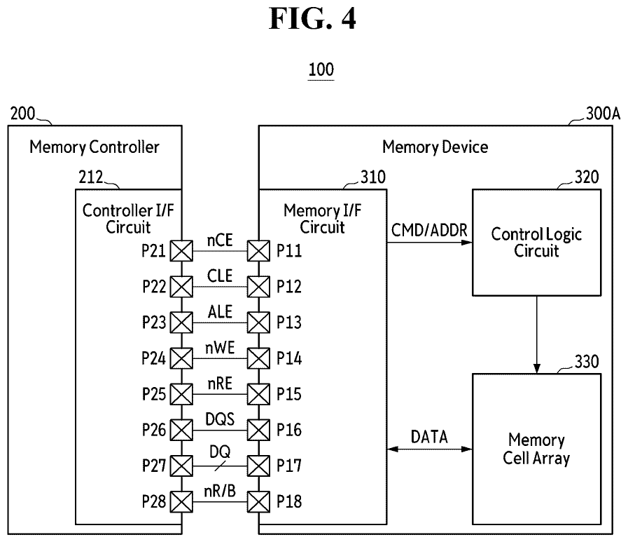

FIG. 4 is a diagram of a storage device, according to some embodiments.

Referring to FIG. 4, the storage device 100 may include a memory controller 200 and a first memory device 300A. The first memory device 300A may include pins (e.g., a first pin P11, a second pin P12, a third pin P13, a fourth pin P14, a fifth pin P15, a sixth pin P16, a seventh pin P17, and an eighth pin P18), a memory interface circuit 310, a control logic circuit 320, and a memory cell array 330.

The memory interface circuit 310 may receive a chip enable signal nCE from the memory controller 200 through the first pin P11. The memory interface circuit 310 may transmit and/or receive signals to and/or from the memory controller 200 through the second to eighth pins P12 to P18 in accordance with the chip enable signal nCE. For example, when the chip enable signal nCE is in an enable status (e.g., a logic high level status), the memory interface circuit 310 may transmit and/or receive signals to and/or from the memory controller 200 through second to eighth pins P12 to P18.

The memory interface circuit 310 may receive a command latch enable signal CLE, an address latch enable signal ALE, and a write enable signal nWE from the memory controller 200 through second to fourth pins P12 to P14, respectively. The memory interface circuit 310 may receive the data signal DQ from the memory controller 200 and/or transmit the data signal DQ to the memory controller 200 through a seventh pin P17. The command CMD, the address ADDR, and the data DATA may be sent through the data signal DQ. For example, the data signal DQ may be sent through a plurality of data signal lines. In such case, the seventh pin P17 may include a plurality of pins corresponding to the plurality of data signals.

The memory interface circuit 310 may acquire the command CMD from the data signal DQ received in an enable section (e.g., a logic high level status) of the command latch enable signal CLE on the basis of toggle timings of the write enable signal nWE. The memory interface circuit 310 may acquire the address ADDR from the data signal DQ received in the enable section (e.g., a logic high level status) of the address latch enable signal ALE on the basis of the toggle timings of the write enable signal nWE.

In an embodiment, the write enable signal nWE may hold a static status (e.g., a logic high level status or a logic low level status) and then may toggle between the logic high level and the logic low level. For example, the write enable signal nWE may toggle at the section in which the command CMD and/or the address ADDR is transmitted. Accordingly, the memory interface circuit 310 may acquire the command CMD and/or the address ADDR on the basis of the toggle timings of the write enable signal nWE.

The memory interface circuit 310 may receive the read enable signal nRE from the memory controller 200 through the fifth pin P15. The memory interface circuit 310 may receive a data strobe signal DQS from the memory controller 200 through the sixth pin P16, and/or may transmit the data strobe signal DQS to the memory controller 200.

In a data DATA output operation of the first memory device 300A, the memory interface circuit 310 may receive the read enable signal nRE that toggles through the fifth pin P15 before output of the data DATA. The memory interface circuit 310 may generate the data strobe signal DQS that toggles on the basis of toggling of the read enable signal nRE. For example, the memory interface circuit 310 may generate the data strobe signal DQS that starts to toggle after a predetermined delay (e.g., tDQSRE) on the basis of a toggling start time of the read enable signal nRE. The memory interface circuit 310 may transmit the data signal DQ including the data DATA on the basis of the toggle timing of the data strobe signal DQS. Accordingly, the data DATA may be arranged at the toggle timing of the data strobe signal DQS and transmitted to the memory controller 200.

In a data DATA input operation of the first memory device 300A, when the data signal DQ including the data DATA is received from the memory controller 200, the memory interface circuit 310 may receive the data strobe signal DQS that toggles together with the data DATA from the memory controller 200. The memory interface circuit 310 may acquire the data DATA from the data signal DQ on the basis of the toggle timing of the data strobe signal DQS. For example, the memory interface circuit 310 may acquire the data DATA by sampling the data signal DQ at a rising edge and a falling edge of the data strobe signal DQS.

The memory interface circuit 310 may transmit a ready/busy output signal nR/B to the memory controller 200 through the eighth pin P18. The memory interface circuit 310 may transmit the status information of the first memory device 300A to the memory controller 200 through the ready/busy output signal nR/B. When the first memory device 300A is in a busy status (e.g., when the internal operations of the first memory device 300A are being performed), the memory interface circuit 310 may transmit the ready/busy output signal nR/B indicating the busy status to the memory controller 200. When the first memory device 300A is in a ready status (e.g., the internal operations of the first memory device 300A are not performed or are completed), the memory interface circuit 310 may transmit the ready/busy output signal nR/B indicating the ready status to the memory controller 200. For example, while the first memory device 300A reads the data DATA from the memory cell array 330 in response to a page read command, the memory interface circuit 310 may transmit the ready/busy output signal nR/B indicating the busy status (e.g., a logic low level) to the memory controller 200. As another example, while the first memory device 300A programs the data DATA to the memory cell array 330 in response to the program command, the memory interface circuit 310 may transmit the ready/busy output signal nR/B indicating the busy status to the memory controller 200.

The control logic circuit 320 may generally control various operations of the first memory device 300A. The control logic circuit 320 may receive the command/address CMD/ADDR acquired from the memory interface circuit 310. The control logic circuit 320 may generate control signals for controlling other constituent elements of the first memory device 300A in accordance with the received command/address CMD/ADDR. For example, the control logic circuit 320 may generate various control signals for programing the data DATA in the memory cell array 330 or reading the data DATA from the memory cell array 330. Alternatively or additionally, the control logic circuit 320 may generate control signals for adjusting a channel potential inside the memory cell array.

The memory cell array 330 may store the data DATA acquired from the memory interface circuit 310 in accordance with the control of the control logic circuit 320. The memory cell array 330 may output the stored data DATA to the memory interface circuit 310 in accordance with the control of the control logic circuit 320. Further, the channel potential inside the memory cell array 330 may be adjusted in accordance with the control of the control logic circuit 320

The memory cell array 330 may include a plurality of memory cells. For example, the plurality of memory cells may be and/or may include flash memory cells. However, the present disclosure is not limited thereto. For example, the memory cells may be and/or may include, but not be limited to, RRAM cells, FRAM cells, PRAM cells, thyristor random-access memory (TRAM) cells, or MRAM cells. Hereinafter, embodiments of the present disclosure are described based on an embodiment in which the memory cells are NAND flash memory cells.

The memory controller 200 may include pins (e.g., a first pin P21, a second pin P22, a third pin P23, a fourth pin P24, a fifth pin P25, a sixth pin P26, a seventh pin P27, and an eighth pin P28), and a controller interface circuit 212. The first to eighth pins P21 to P28 of the memory controller 200 may correspond to the first to eighth pins P11 to P18 of the first memory device 300A.

The controller interface circuit 212 may transmit the chip enable signal nCE to the first memory device 300A through the first pin P21. The controller interface circuit 212 may transmit and/or receive signals to and/or from the first memory device 300A selected through the chip enable signal nCE, through the second to eighth pins P22 to P28.

The controller interface circuit 212 may transmit the command latch enable signal CLE, the address latch enable signal ALE, and the write enable signal nWE to the first memory device 300A through the second to fourth pins P22 to P24. The controller interface circuit 212 may transmit the data signal DQ to the first memory device 300A and/or receive the data signal DQ from the first memory device 300A through the seventh pin P27.

The controller interface circuit 212 may transmit the data signal DQ including the command CMD and/or the address ADDR to the first memory device 300A, along with the toggling write enable signal nWE. The controller interface circuit 212 may transmit the data signal DQ including the command CMD to the first memory device 300A by transmitting the command latch enable signal CLE having the enable status, and may transmit the data signal DQ including the address ADDR to the first memory device 300A by transmitting the address latch enable signal ALE having the enable status.

The controller interface circuit 212 may transmit the read enable signal nRE to the first memory device 300A through the fifth pin P25. The controller interface circuit 212 may receive the data strobe signal DQS from the first memory device 300A through the sixth pin P26, and/or may transmit the data strobe signal DQS to the first memory device 300A.

In the data DATA output operation of the first memory device 300A, the controller interface circuit 212 may generate a toggling read enable signal nRE, and may transmit the read enable signal nRE to the first memory device 300A. For example, the controller interface circuit 212 may generate the read enable signal nRE that changes from the fixed status (e.g., a logic high level or a logic low level) to the toggle status before the data DATA is output. Accordingly, the toggling data strobe signal DQS may be generated in the first memory device 300A on the basis of the read enable signal nRE. The controller interface circuit 212 may receive the data signal DQ including the data DATA along with the toggling data strobe signal DQS from the first memory device 300A. The controller interface circuit 212 may acquire the data DATA from the data signal DQ on the basis of the toggle timing of the data strobe signal DQS.

In the data DATA input operation of the first memory device 300A, the controller interface circuit 212 may generate the toggling data strobe signal DQS. For example, the controller interface circuit 212 may generate a data strobe signal DQS that changes from the fixed status (e.g., a logic high level or a logic low level) to the toggle status before transmitting the data DATA. The controller interface circuit 212 may transmit the data signal DQ including the data DATA to the first memory device 300A on the basis of the toggle timings of the data strobe signal DQS.

The controller interface circuit 212 may receive a ready/busy output signal nR/B from the first memory device 300A through the eighth pin P28. The controller interface circuit 212 may discriminate the status information of the first memory device 300A on the basis of the ready/busy output signal nR/B.

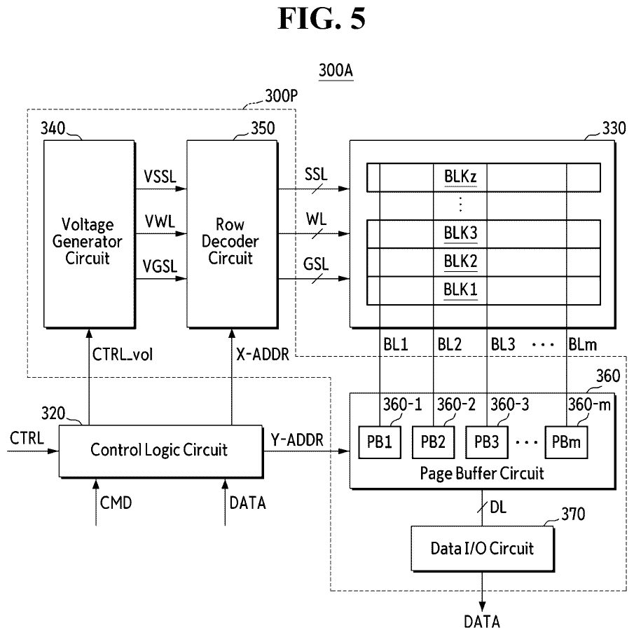

FIG. 5 is a diagram of a memory device, according to some embodiments.

Referring to FIG. 5, a first memory device 300A may include a control logic circuit 320, a peripheral circuit 300P, and a memory cell array 330. The first memory device 300A may further include a memory interface circuit 310 (as shown in FIG. 4), and may further include a column logic, a pre-decoder, a temperature sensor, a command decoder, an address decoder, or the like.

The control logic circuit 320 may control various operations inside the first memory device 300A. For example, the control logic circuit 320 may output various control signals in response to the command CMD and/or the address ADDR received from the memory interface circuit 310. As another example, the control logic circuit 320 may output a voltage control signal CTRL_vol, a row address X-ADDR, and a column address Y-ADDR. The voltage control signal CTRL_vol may include a program signal and/or an erase signal.

The memory cell array 330 may include a plurality of memory blocks (e.g., a first memory block BLK1, a second memory block BLK2, a third memory block BLK3, to a z-th memory block BLKz, where z is a positive integer greater than one (1), and hereinafter generally referred to as BLK), and each of the plurality of memory blocks BLK may include a plurality of memory cells. The memory cell array 330 may be connected to a page buffer circuit 360 through a plurality of bit lines (e.g., a first bit line BL1, a second bit line BL2, a third bit line BL3, to an m-th bit line BLm, hereinafter generally referred to as BL), and may be connected to a row decoder circuit 350 through a plurality of word lines WL, a plurality of string selection lines SSL, and a plurality of ground selection lines GSL.

In an embodiment, the memory cell array 330 may be and/or may include a 3D memory cell array, and the 3D memory cell array may include a plurality of NAND strings. Each NAND string may include memory cells each connected to word lines stacked vertically on a substrate. In an embodiment, the memory cell array 330 may include a 2D memory cell array, and the 2D memory cell array may include a plurality of NAND strings arranged along row and column directions.

The peripheral circuit 300P may include a page buffer circuit 360, a voltage generation circuit 340, a row decoder circuit 350, and a data input/output circuit 370.

The page buffer circuit 360 may include a plurality of page buffers (e.g., a first page buffer PB1 360-1, a second page buffer PB2 360-2, a third second page buffer PB3 360-3, to an m-th second page buffer PBm 360-m, hereinafter generally referred to as PB), and each of the plurality of page buffers PB may be connected to the memory cells through the plurality of bit lines BL. The page buffer circuit 360 may select at least one of the plurality of bit lines BL in response to the column address Y-ADDR. The page buffer circuit 360 may operate as a write driver and/or a sense amplifier depending on the operating mode. For example, at the time of a program operation, the page buffer circuit 360 may apply a bit line voltage corresponding to data to be programmed to the selected bit line. At the time of the read operation, the page buffer circuit 360 may sense the current and/or voltage of the selected bit line to sense the data stored in the memory cell.

The voltage generation circuit 340 may generate various types of voltages for performing soft program, program, read, and/or erase operations on the memory cell array 330 on the basis of the voltage control signal CTRL_vol. For example, the voltage generation circuit 340 may generate a program voltage, a read voltage, a program verification voltage, an erase voltage, or the like, as a word line voltage VWL for driving the plurality of word lines WL. In addition, the voltage generation circuit 340 may generate a string selection line voltage VSSL for driving the plurality of string selection lines SSL, and a ground selection line voltage VGSL for driving the plurality of ground selection lines GSL. For example, the string selection line voltage VSSL may be a string selection voltage (e.g., an on-voltage or an off-voltage). Furthermore, the ground selection line voltage VGSL may be a ground selection voltage (e.g., an on-voltage or an off-voltage).

The row decoder circuit 350 may select one of the plurality of word lines WL, and may select one of the plurality of string selection lines SSL, in response to a row address X-ADDR. For example, at the time of the program operation, the row decoder circuit 350 may apply a program voltage and a program verification voltage to a selected word line, and may apply a pass voltage to an unselected word line. In addition, at the time of the read operation, the row decoder circuit 350 may apply a read voltage to the selected word line and may apply a pass voltage to the unselected word line.

In addition, at the time of the erase operation, the row decoder circuit 350 may apply an erase voltage (e.g., zero (0) Volts (V)) to the word line WL, and may allow each of the string selection line SSL and the ground selection line GSL to float.

The data input/output circuit 370 may be connected to the page buffer circuit 360 through a plurality of data lines DL. At the time of the program operation, the data input/output circuit 370 may receive the program data DATA from the memory controller 200, and may provide the program data DATA to the page buffer circuit 360 on the basis of a column address Y-ADDR provided from the control logic circuit 320. At the time of the read operation, the data input/output circuit 370 may provide the read data DATA stored in the page buffer circuit 360 to the memory controller 200, on the basis of the column address Y-ADDR provided from the control logic circuit 320.

The control logic circuit 320 may perform the soft program operation on the memory cell array 330. The soft program operation may refer to an operation of raising the threshold voltage of the memory cells of the deeply erased status among the memory cells connected to a word line adjacent to the word line WL selected by the row decoder circuit 350 to a threshold voltage of an erased status, at the time of the program operation.

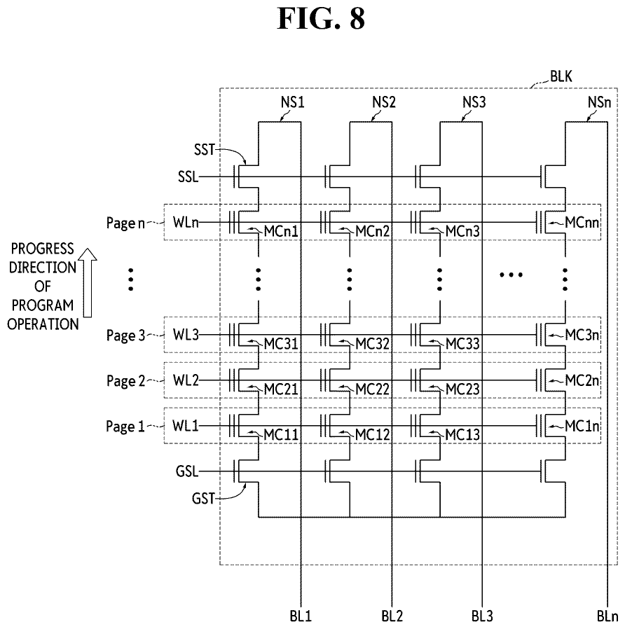

The control logic circuit 320 may discriminate the status of the program data DATA provided from the data input/output circuit 370 to the page buffer circuit 360. The control logic circuit 320 may perform the soft program operation of discriminating the status of data to be programmed in each of the memory cells connected to the selected word line WL, sharing the same bit line as a memory cell to which data of a lower status is expected to be programmed, and raising the threshold voltage to the memory cell connected to the adjacent word line. The soft program operation of the control logic circuit 320 is described below with reference to FIG. 8.

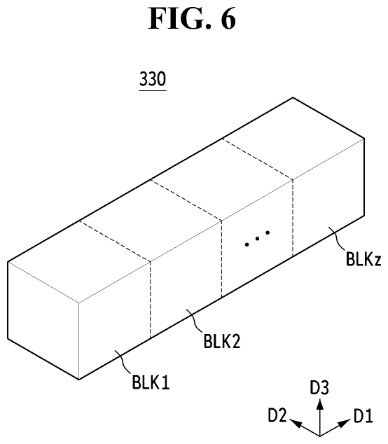

FIG. 6 is a diagram showing an example of the memory cell array of FIG. 5, according to some embodiments.

Referring to FIG. 6, the memory cell array 330 includes the plurality of memory blocks BLK (e.g., the first memory block BLK1, the second memory block BLK2, to the z-th memory block BLKz) disposed along a plurality of directions (e.g., a first direction D1, a second direction D2, and a third direction D3). For example, the first direction D1 may be a vertical direction, and the second and third directions D2 and D3 may be horizontal directions. The plurality of directions D1 to D3 may intersect each other.

The memory blocks may be selected by the row decoder circuit 350. For example, the row decoder circuit 350 may select the first memory block BLK1 corresponding to the block address from among the plurality of memory blocks BLK.

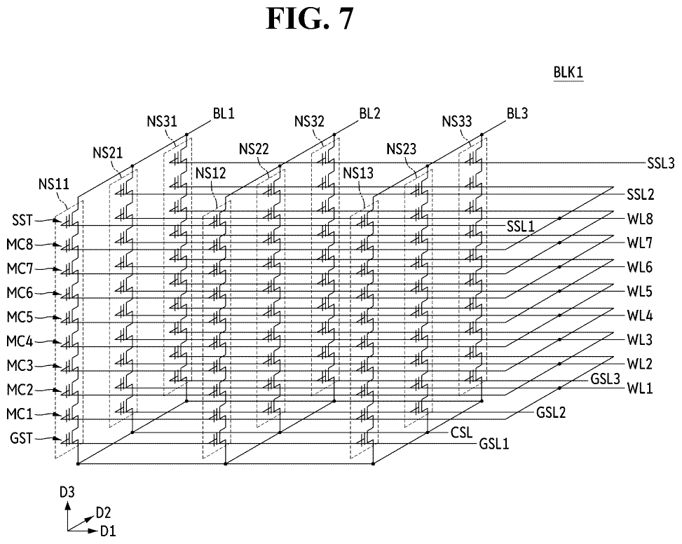

FIG. 7 is a diagram of an example of the memory block of FIG. 5, according to some embodiments.

Referring to FIG. 7, a plurality of cell strings NS11 to NS33 may be disposed between the plurality of bit lines BL (e.g., the first to third bit lines BL1 to BL3) and the common source line CSL. Each cell string (e.g., a first cell string NS11) may include a ground selection transistor GST, a plurality of memory cells (e.g., a first memory cell MC1, a second memory cell MC2, a third memory cell MC3, a fourth memory cell MC4, a fifth memory cell MC5, a sixth memory cell MC6, a seventh memory cell MC, and an eighth memory cell MC8, hereinafter generally referred to as MC), and a string selection transistor SST.

The string selection transistor SST may be connected to the string selection line SSL. The string selection line SSL may be divided into a first string selection line SSL1, a second string selection line SSL2, and a third string selection line SSL3. The ground selection transistor GST may be connected to a plurality of ground selection lines (e.g., a first ground selection line GSL1, a second ground selection line GSL2, and a third ground selection line GSL3, hereinafter generally referred to as GSL). In some embodiments, the plurality of ground selection lines GSL may be connected to each other. The string selection transistor SST may be connected to the plurality of bit lines BL, and the ground selection transistor GST may be connected to a common source line CSL.

The plurality of memory cells MC may be connected to respective word lines of a plurality of word lines WL (e.g., a first word line WL1, a second word line WL2, a third word line WL3, a fourth word line WL4, a fifth word line WL5, a sixth word line WL6, a seventh word line WL7, and an eighth word line WL8). A set of memory cells connected to one word line and programmed simultaneously may be referred to as a page. The first memory block BLK1 may include a plurality of pages. In addition, the plurality of pages may be connected to one word line.

Such a page may be and/or may represent a unit of data programing and/or reading, and the memory block (e.g., the first memory block BLK1) may be and/or may represent a unit of data erasure. That is, when the nonvolatile memory device performs a program or read operation, page units of data may be programmed or read, and when the nonvolatile memory device performs an crase operation, memory block units of data may be erased. That is, data stored in the plurality of memory cells MC included in the single memory block may be erased at once.

Each of the plurality of memory cells MC may store one (1) bit of data and/or two (2) or more bits of data. For example, the first to eighth memory cells MC1 to MC8 may be and/or may include a single level cell (SLC) memory in which one (1) bit of data is written in one memory cell, and/or may be and/or may include a multi-level cell (MLC) that may store two (2) or more bits of data. The MLC may be, for example, a triple level cell (TLC) in which three (3) bits of data are written in one memory cell, and/or a quadruple level cell (QLC) in which four (4) bits of data are written in one memory cell.

FIG. 8 is a diagram of the program operation and the soft program operation on the memory block of FIG. 7, according to some embodiments.

For case of description, FIG. 8 shows a portion of the memory block described above with reference to FIG. 7 to describe an operation in which data is programmed and a soft program operation is performed in the memory block of FIG. 7.

Referring to FIG. 8, the memory block BLK may include a plurality of cell strings (e.g., a first cell string NS1, a second cell string NS2, a third cell string NS3, to an n-th cell string NSn, hereinafter generally referred to as NS). The plurality of cell strings NS may be respectively connected to a plurality of bit lines (e.g., a first bit line BL1, a second bit line BL2, a third bit line BL3, to an n-th bit line BLn, hereinafter generally referred to as BL). Each cell string NS may include a source selection transistor SST, a plurality of memory cells MC, and a ground selection transistor GST. The ground selection transistor GST of each cell string NS may be connected between the plurality of memory cells MC and a common source line CSL. The ground selection transistors GST of the plurality of cell strings NS may be commonly connected to the common source line CSL. The string selection transistor SST of each cell string NS may be connected between the memory cells MC and the bit line BL. The string selection transistors SST of the plurality of cell strings NS may be connected to the plurality of bit lines BL, respectively. In each cell string NS, the plurality of memory cells MC may be provided between the string selection transistor SST and the ground selection transistor GST. In each cell string NS, the plurality of memory cells MC may be connected in series. For example, in the first cell string NS1, the plurality of memory cells (e.g., first memory cells MC11 to MC1n) may be connected in series.

In the plurality of cell strings NS, the memory cells MC located in the same order from the common source line CSL may be commonly connected to a single word line. The memory cells MC (e.g., memory cells MC11 to MCnn) of the plurality of cell strings NS may be connected to the plurality of word lines WL.

The memory cells connected to the same word line inside the plurality of cell strings NS arranged in the row direction may constitute a single page. For example, first memory cells MC11 to MC1n connected to the first word line WL1 inside the plurality of cell strings NS may constitute a first page (e.g., Page 1). Second memory cells MC21 to MC2n connected to the second word line WL2 may constitute a second page (e.g., Page 2). Third memory cells MC31 to MC3n connected to the third word line WL3 may constitute a third page (e.g., Page 3). N-th memory cells MCn1 to MCnn connected to an n-th word line WLn may constitute an n-th page (e.g., Page n).

The first memory device 300A may perform a program operation on a selected memory cell in response to a program command provided from the memory controller 200. The program operation may be performed in units of pages corresponding to each of the plurality of word lines WL.

In some embodiments, the program operation corresponding to the program command of the memory controller 200 may be performed sequentially according to the physical location of the word line corresponding to each page for the plurality of pages. For example, the memory controller 200 may select the first page (e.g., Page 1) to the n-th page (e.g., Page n) as program target pages. The memory controller 200 may control the first memory device 300A so that the program operation is performed sequentially from the first page (e.g., Page 1) to the n-th page (e.g., Page n).

However, the order of the program operations for the plurality of pages is not limited thereto. For example, the memory controller 200 may control the first memory device 300A so that the program operation is performed sequentially from the n-th page (e.g., Page n) to the first page (e.g., Page 1).

In the following description, a case where the program operation on the plurality of pages is performed sequentially from the first page (e.g., Page 1) to the n-th page (e.g., Page n) is described as an example. That is, after the program operation on the first memory cells MC11 to MC1n connected to the first word line WL1 is performed, the program operation on the second memory cells MC21 to MC2n connected to the second word line WL2 may be performed. The program operation on the third memory cells MC31 to MCnn connected to each of the third to n-th word lines WL3 to WLn may be performed sequentially.

The control logic circuit 320 may be controlled to perform the soft program operation on the memory cells connected to a word line (hereinafter, an adjacent word line) adjacent to the selected word line first, before the program operation on the memory cells connected to a word line (hereinafter, a selected word line) selected by the row decoder circuit 350 at the time of the program operation. For example, the adjacent word line may refer to a word line on which the program operation is performed next after the program operation on the selected word line is performed.

For example, when the row decoder circuit 350 selects the page (e.g., Page 1) as the page to be programmed first, the control logic circuit 320 may perform the soft program operation on the second word line WL2 on which the program operation is performed following the first word line WL1, before performing the program operation on the first memory cells MC11 to MC1n connected to the first word line WL1.

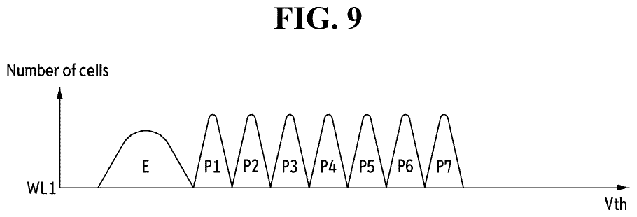

The control logic circuit 320 may repeat the soft program operation on the adjacent word lines and the program operation on the selected word line, until the program operation on the plurality of word lines WL is completed. For example, the control logic circuit 320 may perform the program operation on the memory cells connected to the first word line WL1 after the soft program operation on the memory cells connected to the second word line WL2 is completed. Further, the control logic circuit 320 may perform the soft program operation on the memory cells connected to the third word line WL3, before performing the program operation on the memory cells connected to the second word line WL2. The soft program operation of the control logic circuit 320 is described below with reference to FIGS. 9 to 17.

FIG. 9 is a diagram showing an example of a threshold voltage distribution of the memory cells when data is programmed to the memory cells connected to any one of the word lines of FIG. 8, according to some embodiments.

The following description of FIGS. 9 to 20 is provided by referring to the memory block BLK described with reference to FIG. 8. In the following description, a case where the memory cells MC11 to MCnn are triple-level cells (TLC) that store three (3) data bits are described as an example. In the following description, although the first word line WL1 from among the plurality of word lines WL is described as an example, the description of the first word line WL1 may be equally applied to the remaining second to n-th word lines WL2 to WLn.

Referring to FIG. 9, after the program operation on the first memory cells MC11 to MC1n connected to the first word line WL1 is completed, the first memory cells MC11 to MC1n connected to the first word line WL1 may have a threshold voltage of the erased status E and any one status of the first to seventh program statuses P1 to P7.

As a result, data to be programmed in the first memory cells MC11 to MC1n connected to the first word line WL1 may be divided into data of lower status (hereinafter, lower data) and data of upper status (hereinafter, upper data) depending on the magnitude of the threshold voltage of each first memory cell MC11 to MC1n when data is actually programmed in the first memory cells MC11 to MC1n.

For example, when data is programmed in the first memory cells MC11 to MC1n, in a case where the memory cell has a threshold voltage of the erased status E or a threshold voltage of any one program status from among the program statuses (e.g., a first program status P1, a second program status P2, and a third program status P3), data to be programmed in the corresponding memory cell may be determined to be a lower data.

Alternatively or additionally, when data is programmed in the first memory cells MC11 to MC1n, in a case where the memory cell has a threshold voltage of any one program status from among the fourth to seventh program statuses P4 to P7, the data to be programmed in the corresponding memory cells may be determined to be an upper data.

As a result, the criterion for distinguishing between the upper data and the lower data may be based on the magnitude of the threshold voltage of the memory cells. However, in an embodiment in which the memory cell is a TLC, the upper data does not always correspond to the fourth to seventh program statuses P4 to P7, and the lower data does not always correspond to the erased status E and the first to third program states P1 to P3. That is, the magnitude of the threshold voltage that is the criterion for dividing the upper data and the lower data may vary depending on the embodiments.

However, the following description is provided on the assumption that the upper data corresponds to the fourth to seventh program statuses P4 to P7, and the lower data corresponds to the erased status E and the first to third program states P1 to P3, in the embodiment in which the memory cell is a TLC.

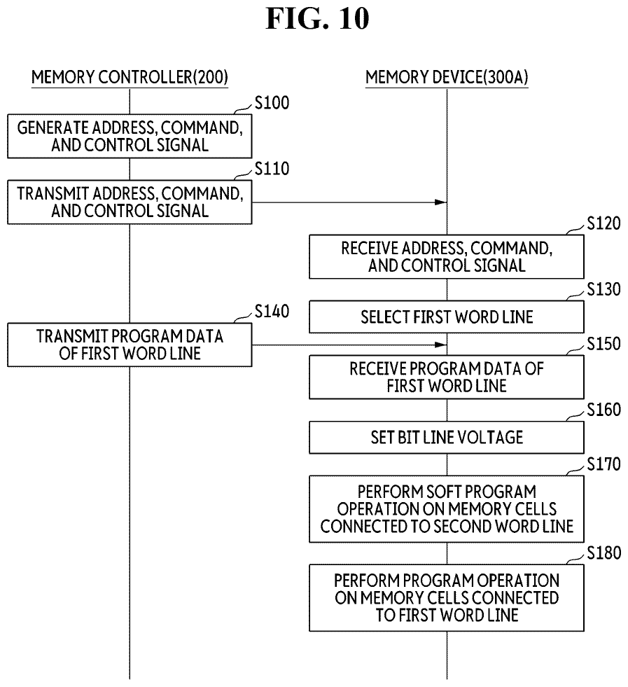

FIG. 10 is a flowchart of the operation of the storage device, according to some embodiments.

The following description depicts an example in which the first page (e.g., Page 1) of FIG. 8 is selected as the page to be programmed by the row decoder circuit 350, and the second page (e.g., Page 2) is selected as the page to be next programmed.

Referring to FIG. 10, the memory controller 200 may generate an address ADDR, a command CMD, and a control signal CTRL, and transmit the generated address ADDR, command CMD, and control signal CTRL to the first memory device 300A (operations S100 and S110). The first memory device 300A may receive the address ADDR, the command CMD, and the control signal CTRL from the memory controller 200 (operation S120).

For example, the control signal CTRL transmitted by the memory controller 200 may be for controlling the program operation and the soft program operation on the first memory device 300A. The command CMD transmitted by the memory controller 200 may be the program command and the soft program command on the first memory device 300A. The address ADDR transmitted by the memory controller 200 may include an address for a memory block in which data is to be programmed among a plurality of memory blocks included in the memory cell array 330, and an address for a page (or word line) in which data is to be programmed from among a plurality of pages (or a plurality of word lines) included in the memory block.

The first memory device 300A may select the first word line WL1 as the word line in which data is to be programmed on the basis of the address ADDR, the command CMD, and the control signal CTRL received from the memory controller 200 (operation S130). In particular, the row decoder circuit 350 may select the first word line WL1 from among the plurality of word lines WL as the word line to be programmed, on the basis of the row address X-ADDR received from the control logic circuit 320.

The memory controller 200 may transmit the data to be programmed in the memory cells connected to the first word line WL1 to the first memory device 300A (operation S140), and the first memory device 300A may receive data to be programmed in the memory cells connected to the first word line WL1 from the memory controller 200 (operation S150). For example, the data to be programmed in each of the first memory cells MC11 to MC1n may be sent to the page buffer circuit 360 through the data input/output circuit 370. For example, the data to be programmed in each of the first memory cells MC11 to MC1n may be stored in a page buffer connected to the bit line connected to the corresponding memory cell.

For example, data to be programmed in the first memory cell MC11 may be stored in the first page buffer PB1 360-1 connected to first bit line BL1. Similarly, data to be programmed in the second memory cell M12 may be stored in the second page buffer PB2 360-2 connected to the second bit line BL2.

The first memory device 300A may set a bit line voltage on the basis of the data to be programmed in the memory cells connected to the first word line WL1 (operation S160). The bit line voltage setting operation may be controlled by the control logic circuit 320. For example, the control logic circuit 320 may check the data to be programmed in the memory cells connected to the first word line WL1 stored in a page buffer connected to the bit line connected to the memory cell, for each memory cell.

Subsequently, the control logic circuit 320 may apply a first voltage to the bit line connected to that memory cell when the data to be programmed to the memory cell corresponds to the lower data, and may apply a second voltage to the bit line connected to that memory cell when the data to be programmed to the memory cell corresponds to the upper data. In an embodiment, the magnitude of the first voltage may be smaller than the magnitude of the second voltage. For example, the first voltage may be a ground voltage (e.g., OV) and the second voltage may be a power supply voltage. However, the present disclosure is not limited thereto.

The first memory device 300A may perform the soft program operation on the memory cells connected to the second word line WL2 (operation S170). The second word line WL2 may be a word line adjacent to the first word line WL1, and may be a word line selected to be programmed following the first word line WL1. The soft program operation may be performed, by applying the soft program voltage to the second word line WL2 through the row decoder circuit 350 using the voltage generation circuit 340 by the control of the control logic circuit 320 in the state in which the voltage setting for the bit line is completed.

The first memory device 300A may perform the program operation on the memory cells connected to the first word line WL1, after the soft program operation on the memory cells connected to the second word line WL2 is completed (operation S180). The program operation on the memory cell connected to the first word line WL1 may be performed, by applying the program voltage to the first word line WL1 using the voltage generation circuit 340 through the row decoder circuit 350 by the control of the control logic circuit 320 by an incremental step pulse programming (ISPP) method.

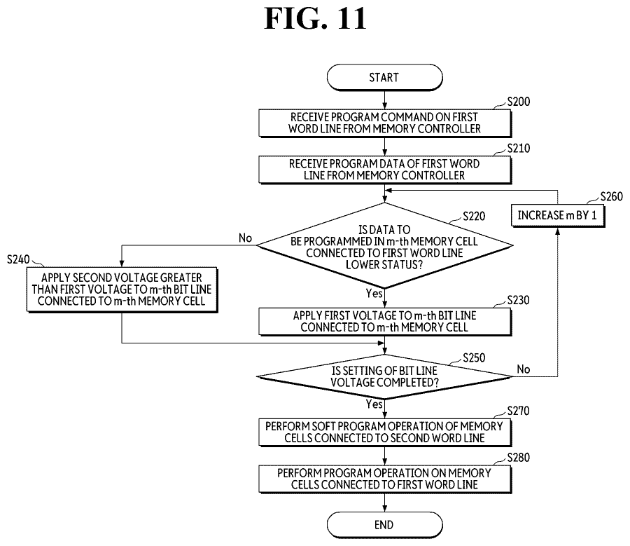

FIG. 11 is a flowchart of the operation of the memory device, according to some embodiments. In the following description, a case is described in which the memory controller 200 generates a program command on the first word line WL1, the first to m-th memory cells are connected to the first word line WL1, and the first to m-th memory cells are connected to each of the first to m-th bit lines.

Referring to FIG. 11, the control logic circuit 320 may receive the program command on the first word line WL1 from the memory controller 200, and may receive program data of the first word line WL1 from the memory controller 200 (operations S200 and S210). The control logic circuit 320 may determine whether the data to be programmed in the first memory cell is in a lower status (operation S220). For example, if the data to be programmed in the first memory cell is determined to be in a lower status (Yes in operation S220), the control logic circuit 320 may apply a first voltage to the first bit line connected to the first memory cell. If the data to be programmed in the first memory cell is not determined to be in a lower status (No in operation S220), the control logic circuit 320 may apply the second voltage greater than the first voltage to the first bit line connected to the first memory cell.

If the voltage setting operation for all bit lines connected to each of the memory cells connected to the first word line WL1 is not completed (No in S250), the control logic circuit 320 may repeat the aforementioned operation (operation S260).

If the voltage setting operation for all bit lines connected to each of the memory cells connected to the first word line WL1 is completed (Yes in operation S250), the control logic circuit 320 may perform the soft program operation on the memory cells connected to the second word line WL2 which is adjacent to the first word line WL1 and on which the program operation is to be performed following the first word line WL1 (operation S270). When the soft program operation on the memory cells connected to the second word line WL2 is completed, the control logic circuit 320 may perform the program operation on the memory cells connected to the first word line WL1 (operation S280).

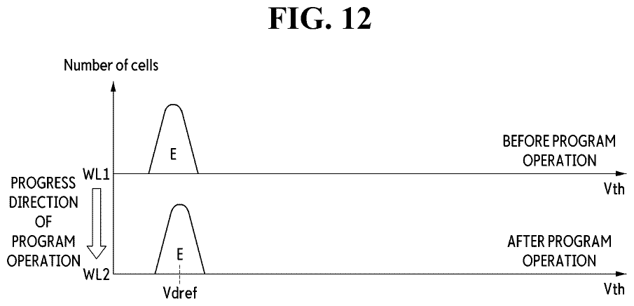

FIG. 12 is a diagram showing the threshold voltage distribution of the memory cells before the program operation is performed on the memory cells connected to the selected word line and the memory cells connected to the adjacent word line, according to some embodiments.

In FIG. 12, an upper graph shows a threshold voltage distribution of the first memory cells MC11 to MC1n connected to the first word line WL1, before the program operation is performed on the first memory cells MC11 to MC1n connected to the first word line WL1 from among the plurality of word lines WL of the memory cell array 330. Referring to the upper graph of FIG. 12, since the first memory cells MC11 to MC1n connected to the first word line WL1 are in a state before the program operation is performed, the threshold voltage distribution of the first memory cells MC11 to MC1n connected to the first word line WL1 may correspond to an erased status E.

A lower graph shows a threshold voltage distribution of the second memory cells MC21 to MC2n connected to the second word line WL2, before the program operation is performed on the second memory cells MC21 to MC2n connected to the second word line WL2. In an embodiment, the first word line WL1 may be a selected word line (e.g., a word line selected as a word line to be programmed by the row decoder circuit 350), and the second word line WL2 may be an adjacent word line (e.g., a word line which is adjacent to the first word line WL1 and on which the program operation is performed following the first word line WL1).

Referring to the lower graph of FIG. 12, since the memory cells connected to the second word line WL2 are before the program operation is performed, the threshold voltage distribution of the memory cells connected to the second word line WL2 may correspond to the erased status E. For example, deeply erased cells may be included among the memory cells connected to the second word line WL1. The deeply erased cells may be memory cells having a threshold voltage lower than a deep erase reference voltage Vdref. The deep erase reference voltage Vdref may be a voltage for distinguishing between the erased status E and the deeply erased status. The magnitude of the deep erase reference voltage Vdref may be equal to the lowest threshold voltage among the threshold voltages included in the erased status E. However, the present disclosure is not limited in this regard.

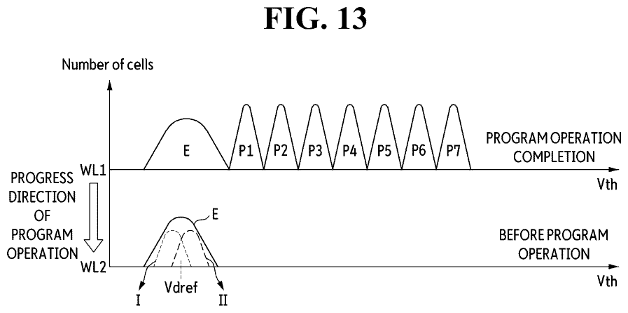

FIG. 13 is a diagram showing the threshold voltage distribution of the memory cells, after the program operation on the memory cells connected to the selected word line is completed and before the program operation on the memory cells connected to the adjacent word line is performed, according to some embodiments.

In FIG. 13, an upper graph shows the threshold voltage distribution of the first memory cells MC11 to MC1n connected to the first word line WL1, after the program operation on the first memory cells MC11 to MC1n connected to the first word line WL1 among the plurality of word lines WL is completed. A lower graph shows the threshold voltage distribution of the second memory cells MC21 to MC2n connected to the second word line WL2, before the program operation on the second memory cells MC21 to MC2n connected to the second word line WL2 is performed, after the program operation on the first memory cells MC11 to MC1n connected to the first word line WL1 is completed.

Referring to the upper graph of FIG. 13, after the program operation on the first memory cells MC11 to MC1n connected to the first word line WL1 is completed, the first memory cells MC11 to MC1n connected to the first word line WL1 may have a threshold voltage of the erased status E or any one status of the first to seventh program statuses P1 to P7.

Referring to the lower graph of FIG. 13, when the program operation on the first memory cells MC11 to MC1n connected to the first word line WL1 is completed, the threshold voltage distribution of the second memory cells MC21 to MC2n, which is connected to the second word line WL2 adjacent to the first word line WL1 and is in the erased status E, may be dualized into a low voltage status I and a high voltage status II.

For example, the memory cells that are in the low voltage status I may be the deeply erased cells. That is, when the threshold voltage distribution of the memory cells that are in the erase status E are dualized into the low voltage status I and the high voltage status II, the memory cells that are in the low voltage status I may be regarded as memory cells having a threshold voltage lower than that of the deep erase reference voltage Vdref, and may be determined to be the deeply erased cells.

For example, the memory cell corresponding to the low voltage status I from among the second memory cells MC21 to MC2n connected to the second word line WL2 may share the same bit line as the memory cell in which the lower data is programmed among the first memory cells MC11 to MC1n connected to the first word line WL1. In addition, the memory cell corresponding to the high voltage status II among the second memory cells MC21 to MC2n connected to the second word line WL2 may share the same bit line as the memory cell in which the upper data is programmed among the first memory cells MC11 to MC1n connected to the first word line WL1.

For example, referring to FIG. 8, when the lower data is programmed in the memory cell MC11 at the time of the program operation on the first page (e.g., Page 1), the threshold voltage of the erased status E of the memory cell MC21 connected to the second word line WL2, which shares the first bit line BL1 with the memory cell MC11, is adjacent to the first word line WL1, and is to be programmed following the first word line WL1, may decrease. That is, the threshold voltage of the erased status E of the memory cell MC21 decreases as a result of the programming of the lower data of the memory cell MC11, and may correspond to the low voltage status I.

Alternatively, when the upper data is programmed in the memory cell MC12, the threshold voltage of the erased status E of the memory cell MC22 connected to the second word line WL2, which shares the second bit line BL2 with the memory cell MC12, is adjacent to the first word line WL1, and is to be programmed following the first word line WL1, may increase. That is, the threshold voltage of the erased status E of the memory cell MC22 increases as a result of the programming of the upper data of the memory cell MC12, and may correspond to the high voltage status II.

As a result, before the memory cells connected to the second word line WL2 are programmed, the threshold voltage distribution of the memory cells connected to the second word line WL2 which are in the erased status E are subjected to interference by programming of data into the memory cells connected to the adjacent first word line WL1, and may be dualized into the low voltage status I and the high voltage status II.

For example, the deeply erased cells corresponding to the low voltage status I may degrade the threshold voltage of the memory cells connected to the word line adjacent to the deeply erased cell. Therefore, before performing the program operation on the memory cells connected to the second word line WL2, it may be necessary to perform an operation of raising the threshold voltage of the deeply erased cells among the memory cells connected to the second word line WL2.

As used herein, the program operation of raising the threshold voltage of the deeply erased cells among the memory cells connected to the adjacent word line of the erased status before performing the program operation on the memory cells connected to the adjacent word line is referred to as a soft program operation.

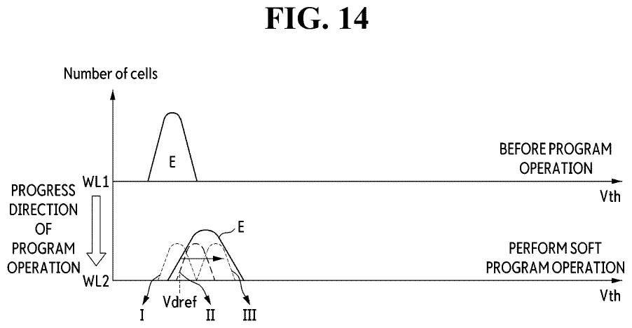

FIG. 14 is a diagram showing the threshold voltage distribution of the memory cells when a soft program operation is performed on the memory cells connected to the adjacent word line before the program operation is performed on the memory cells connected to the selected word line, according to some embodiments.

In FIG. 14, an upper graph shows the threshold voltage distribution of the first memory cells MC11 to MC1n connected to the first word line WL1, before the program operation is performed on the first memory cells MC11 to MC1n connected to the first word line WL1 among the plurality of word lines WL. Referring to the upper graph of FIG. 14, since the first memory cells MC11 to MC1n connected to the first word line WL1 are before the program operation, the threshold voltage distribution of the first memory cells MC11 to MC1n connected to the first word line WL1 may correspond to the erased status E.

A lower graph shows that the threshold voltage of the memory cells of the low voltage status I corresponding to the deeply erased cells increases, by performing the soft program operation on the second memory cells MC21 to MC2n connected to the second word line WL2.

Referring to the lower graph of FIG. 14, when the threshold voltage of the memory cells of the low voltage status I increases and the soft program operation is completed, the threshold voltage distribution of the memory cells of the low voltage status I may be changed to a first rise voltage status III. The magnitude of the threshold voltage of the memory cells of the first rise voltage status III may be greater than the deep erase reference voltage Vdref. Furthermore, the magnitude of the threshold voltage of the memory cells of the first rise voltage status III may be greater than the magnitude of the threshold voltage of the memory cells of the high voltage status II.

For example, since the soft program operation is performed only on the memory cells of the low voltage status I corresponding to the deeply erased cells, the threshold voltage distribution of the memory cells of the high voltage status II may not shift. As a result, the soft program operation on the second memory cells MC21 to MC2n connected to the second word line WL2, which is the adjacent word line, may be performed earlier than the program operation on the first memory cells MC11 to MC1n connected to the first word line WL1, which is the selected word line.

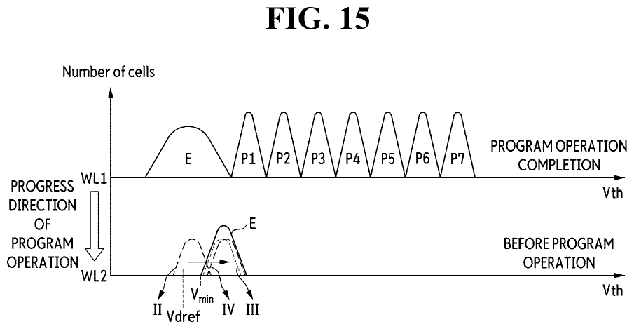

FIG. 15 is a diagram showing the threshold voltage distribution of the memory cells after the program operation on the memory cells connected to the selected word line is completed and before the program operation on the memory cells connected to the adjacent word line subjected to the soft program operation is performed, according to some embodiments.

In FIG. 15, an upper graph shows the threshold voltage distribution of the memory cells connected to the first word line WL1 after the program operation on the first memory cells MC11 to MC1n connected to the first word line WL1 among the plurality of word lines WL is completed. A lower graph shows the threshold voltage distribution of the second memory cells MC21 to MC2n connected to the second word line WL2, after the program operation on the first memory cells MC11 to MC1n connected to the first word line WL1 is completed, and before the program operation on the second memory cells MC21 to MC2n connected to the second word line WL2 is performed.

Referring to the upper graph of FIG. 15, when the program operation on the first memory cells MC11 to MC1n connected to the first word line WL1 is completed, the first memory cells MC11 to MC1n connected to the first word line WL1 may have a threshold voltage of the erased status E and any one program status among the first to seventh program statuses P1 to P7.

Referring to the lower graph of FIG. 15, when the program operation on the first memory cells MC11 to MC1n connected to the first word line WL1 is completed, the magnitude of the threshold voltage of the memory cells corresponding to the high voltage status II among the second memory cells MC21 to MC2n connected to the second word line WL2 may increase. That is, the memory cells corresponding to the high voltage status II among the second memory cells MC21 to MC2n connected to the second word line WL2 are subjected to interference by programming the upper data in the first memory cells MC11 to MC1n connected to the first word line WL1. Thus, the threshold voltage distribution may be changed from the high voltage status II to a second rise voltage status IV.

For example, the threshold voltage distribution of the first rise voltage status III and the second rise voltage status IV may be substantially the same. As a result, it may be possible to alleviate and/or prevent a phenomenon in which the threshold voltage distribution of the second memory cells MC21 to MC2n connected to the second word line WL2 of the erased status E is dualized into the low voltage status I and the high voltage status II, due to interference caused by programming of data into the first memory cells MC11 to MC1n connected to the first word line WL1 before the program operation is performed on the second memory cells MC21 to MC2n connected to the second word line WL2, and it may be possible to reduce the width of the threshold voltage distribution of the second memory cells MC21 to MC2n connected to the second word line WL2 which is in the erased status E.

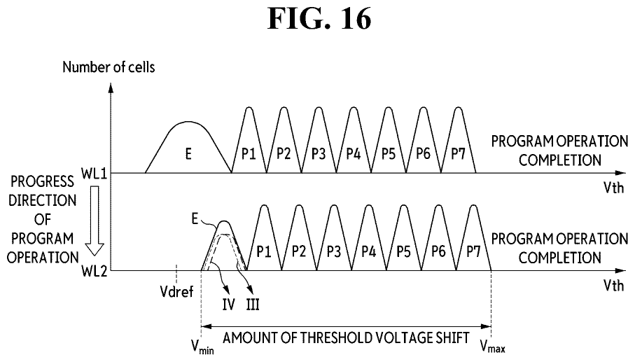

FIG. 16 is a diagram showing the threshold voltage distribution of the memory cells when the program operation on the memory cells connected to the selected word line is completed and the program operation is performed on the memory cells connected to the adjacent word line in which the soft program operation is completed, according to some embodiments.

The description of an upper graph of FIG. 16 may be similar in many respects as the description of the upper graph in FIG. 15, and therefore, repeated descriptions thereof may be omitted for the sake of brevity.

In FIG. 16, a lower graph shows the threshold voltage distribution of the second memory cells MC21 to MC2n connected to the second word line WL2 after the program operation on the second memory cells MC21 to MC2n connected to the second word line WL2 is completed. Referring to the lower graph of FIG. 16, after the program operation on the second memory cells MC21 to MC2n connected to the second word line WL2 is completed, the second memory cells MC21 to MC2n connected to the second word line WL2 may have a threshold voltage of the erased status E or any one of the program statuses from among the first to seventh program statuses P1 to P7.

In order to potentially prevent and/or alleviate the threshold voltage distribution of the second memory cells MC21 to MC2n connected to the adjacent word line WL2 from being subjected to interference by programming of data into the first memory cells MC11 to MC1n connected to the first word line WL1 which is the selected word line, the amount of threshold voltage shift of the second memory cells MC21 to MC2n connected to the second word line WL2 may need to be as small as possible after data is programmed in the first memory cells MC11 to MC1n connected to the first word line WL1 to form a threshold voltage distribution.

Referring to the lower graph of FIG. 16, the amount of threshold voltage shift of the second memory cells MC21 to MC2n connected to the second word line WL2 may correspond to a difference (e.g., Vₘₐₓ−Vₘᵢₙ) between a maximum value Vₘₐₓ and a minimum value Vₘᵢₙ of the threshold voltage when the program operation is completed on the second memory cells MC21 to MC2n connected to the second word line WL2.

According to the present disclosure, before the program operation on the first memory cells MC11 to MC1n connected to the first word line WL1, and the program operation on the second memory cells MC21 to MC2n connected to the second word line WL2 are performed, the soft program operation on the second memory cells MC21 to MC2n connected to the second word line WL2 may be performed first.

Therefore, compared to a case where the program operation on the first memory cells MC11 to MC1n connected to the first word line WL1 is performed, and then the soft program operation on the second memory cells MC21 to MC2n connected to the second word line WL2 is performed, the minimum value Vₘᵢₙ of the threshold voltage may be larger when the program operation on the second memory cells MC21 to MC2n connected to the second word line WL2, which may be the determination criterion for the amount of threshold voltage shift of the second memory cells MC21 to MC2n connected to the second word line WL2.

Accordingly, the amount of threshold voltage shift of the second memory cells MC21 to MC2n connected to the second word line WL2 decreases, and as such, it may be possible to alleviate the phenomenon in which the threshold voltage distribution of the second memory cells MC21 to MC2n connected to the second word line WL2 is subjected to interference by programming of data into the first memory cells MC11 to MC1n connected to the first word line WL1.

In the foregoing, although the case described above has first word line WL1 as the selected word line and the second word line WL2 as the adjacent word line as an example, the above description may be equally applied to a case where any one of the word lines WL2 to WLn other than the first word line WL from among the plurality of word lines WL2 to WLn that constitute the memory block BLK is the selected word line.

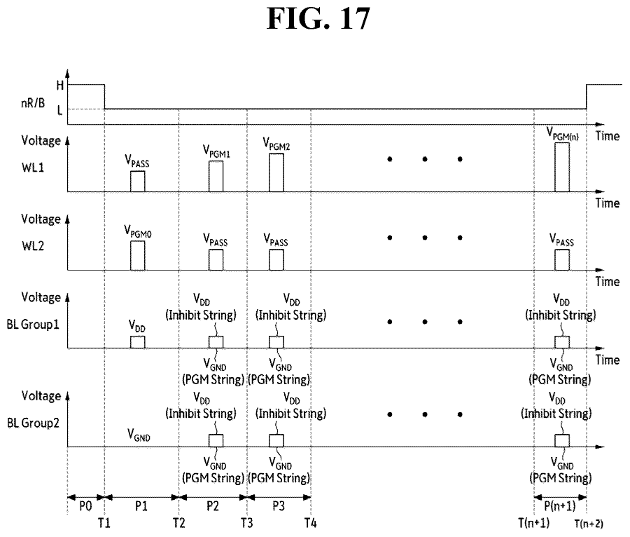

FIG. 17 is a diagram of a program operation of a memory device according to the method of FIG. 10, according to some embodiments.

Referring to FIG. 17, a ready/busy output signal nR/B during time interval P0 may be a logic high H. During the time interval P0, the memory interface circuit 310 may transmit the ready/busy output signal nR/B indicating a ready status to the memory controller 200. At time point T1, the ready/busy output signal nR/B may transition to a logic low L. Thereafter, the ready/busy output signal nR/B may remain in the logic low L status until time point T(n), and then may transition to the logic high H at the time point T(n). During the time interval from time point T1 to time point T(n+2), the memory interface circuit 310 may transmit the ready/busy output signal nR/B indicating the busy status to the memory controller 200. During the time interval from time point T1 to time point T(n+2), the first memory device 300A may perform the program operation on the first memory cells MC11 to MC1n connected to the first word line WL1 and perform the soft program operation on the second memory cells MC21 to MC2n connected to the second word line WL2 in response to a program command and a soft program command from the memory controller 200.

During the time interval P1, the soft program operation may be performed on the second memory cells MC21 to MC2n connected to the second word line WL2, and when the soft program operation is completed, the program operation may be performed on the first memory cells MC11 to MC1n connected to the first word line WL1 during the time interval P2 to time interval P(n+1). As a result, the time interval during which the program voltage is applied to the first word line WL1 which is the selected word line, may not overlap the time interval during which the soft program voltage is applied to the second word line WL2 which is the adjacent word line.

During the time interval P1, a pass voltage V_{PASS} may be applied to the first word line WL1, and a soft program voltage V_{PGM0} may be applied to the second word line WL2. For example, the bit lines constituting the memory cell array may be divided into a second bit line group (e.g., BL Group2) or a first bit line group (e.g., BL Group1) depending on whether the first voltage V_{GND} or the second voltage V_{DD} is applied. The second voltage V_{DD} may be applied to the bit lines included in the first bit line group (e.g., BL Group1), and the first voltage V_{GND} smaller the second voltage V_{DD} may be applied to the bit lines included in the second bit line group (e.g., BL Group2).

The bit lines included in the first bit line group (e.g., BL Group1) may be connected to the memory cells in which the upper data is to be programmed during the time interval P2 to the time interval P(n+1), among the first memory cells MC11 to MC1n connected to the first word line WL1. The bit lines included in the second bit line group (e.g., BL Group2) may be connected to the memory cells in which the lower data is to be programmed during the time interval P2 to the time interval P(n+1), among the first memory cells MC11 to MC1n connected to the first word line WL1.

As a result, among the second memory cells MC21 to MC2n connected to the second word line WL2 during the time interval P1, the first voltage V_{GND} may be applied to the bit lines connected to the bit lines which are subjected to the soft program operation and require removal of the deep erase voltage, and the second voltage V_{DD} may be applied to the bit lines connected to the memory cells that do not require removal of the deep erase voltage. As a result, among the second memory cells MC21 to MC2n connected to the second word line WL2, only the threshold voltage distribution of the memory cells adjacent to the memory cells in which lower data is expected to be programmed among the first memory cells MC11 to MC1n connected to the first word line WL1 may be raised above the deep erase reference voltage Vdref to remove the deeply erased cells.

When performing the program operation on the first memory cells MC11 to MC In connected to the first word line WL1, the program voltage applied to the first word line WL1 may be determined in accordance with an incremental step pulse programming method. That is, the level of the program voltage may increase gradually by the step voltage as the program loop is repeated (e.g., V_{PGM(n)}> . . . >V_{PGM2}>V_{PGM1}). The number of application times of the program voltages, the voltage level, the voltage application time, and the like used in each program loop may be determined in various forms according to the control of the memory controller 200.

While the program loops are repeated at the time intervals P2 to P(n+1), the pass voltage V_{PASS} may be applied to the second word line WL2. In addition, the voltages applied to the bit lines included in the first bit line group (e.g., BL Group1) and the bit lines included in the second bit line group (e.g., BL Group2) may be determined depending on whether the memory cells connected to the bit lines are programmed or inhibited. For example, when that bit line corresponds to a cell string (e.g., PGM String) to be programmed, the first voltage V_{GND} may be applied to the bit line, and when the bit line corresponds to an inhibit string to be not programmed, the second voltage V_{DD} may be applied to the bit line.

As a result, before performing the program operation on the selected word line on the basis of the data pattern of the selected word line, the soft program operation on the memory cells connected to the adjacent word line may be performed sequentially on the word lines connected to the memory cell array.

For example, referring to FIG. 8 together, FIG. 17 exemplarily shows performing the soft program operation on the second memory cells MC21 to MC2n connected to the second word line WL2 before performing the program operation on the first memory cells MC11 to MC1n connected to the first word line WL1. When the program operation on the first memory cells MC11 to MC1n connected to the first word line WL1 is completed, the soft program operation may be performed on the memory cells MC31 to MC3n connected to the third word line WL, before performing the program operation on the second memory cells MC21 to MC2n connected to the second word line WL2. Subsequently, when the soft program operation on the memory cells MC31 to MC3n connected to the third word line WL is completed, the program operation on the second memory cells MC21 to MC2n connected to the second word line WL2 may be performed.

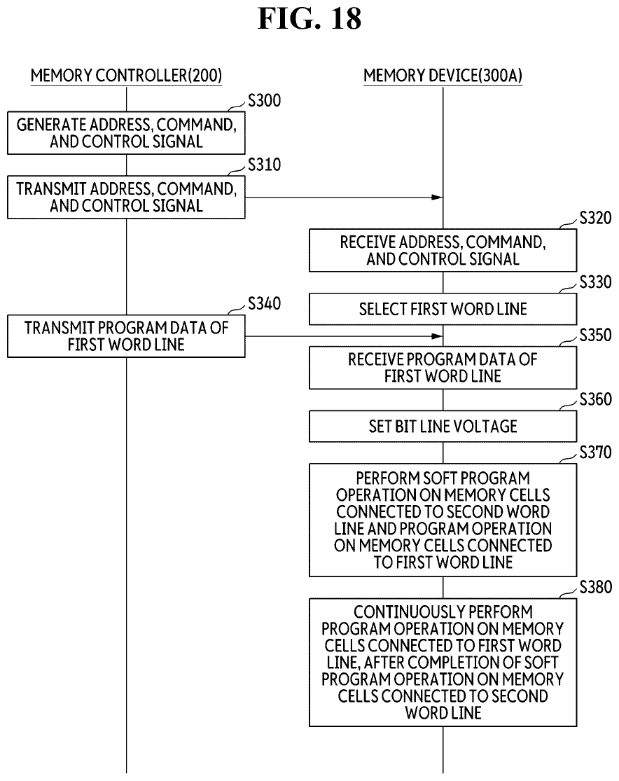

FIG. 18 is a flowchart of the operation of the storage device, according to some embodiments.

Hereinafter, repeated descriptions of above examples may be omitted for the sake of brevity, and the differences may be mainly described.

Referring to FIG. 18, the memory controller 200 may generate an address ADDR, a command CMD, and a control signal CTRL, and transmit the generated address ADDR, command CMD, and control signal CTRL to the first memory device 300A (operations S300 and S310). The first memory device 300A may receive the address ADDR, the command CMD, and the control signal CTRL from the memory controller 200 (operation S320).

The first memory device 300A may select the first word line WL1 as the word line to program data on the basis of the address ADDR, the command CMD, and the control signal CTRL received from the memory controller 200 (operation S330).

The memory controller 200 may transmit the data to be programmed to the memory cells connected to the first word line WL1 (operation S340), and the first memory device 300A may receive data to be programmed in the memory cells connected to the first word line WL1 from the memory controller 200 (operation S350). The first memory device 300A may set a bit line voltage on the basis of data to be programmed in the memory cells connected to the first word line WL1 (operation S360).

The first memory device 300A may simultaneously (e.g., at a substantially similar time period) perform the soft program operation on the memory cells connected to the second word line WL2 and the program operation on the memory cells connected to the first word line WL1 (operation S370). When the soft program operation on the memory cells connected to the second word line WL2 is completed, the first memory device 300A may continue to perform the program operation on the memory cells connected to the first word line WL1 (operation S380).

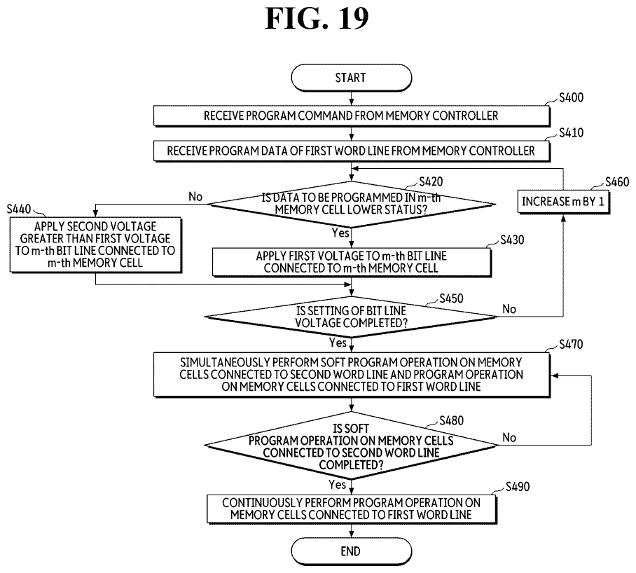

FIG. 19 is a flowchart of an operation of a memory device, according to some embodiments.

Referring to FIG. 19, the control logic circuit 320 may receive the program command on the first word line WL1 from the memory controller 200, and may receive program data of the first word line WL1 from the memory controller 200 (operations S400 and S410). The control logic circuit 320 may determine whether the data to be programmed in the first memory cell is in a lower status (operation S420). For example, if the data to be programmed in the first memory cell is determined to be in the lower status (Yes in operation S420), the control logic circuit 320 may apply a first voltage to the first bit line BL1 connected to the first memory cell (operation S430). If the data to be programmed in the first memory cell is determined not to be in the lower status (No in operation S420), the control logic circuit 320 may apply a second voltage greater than the first voltage to the first bit line BL1 connected to the first memory cell (operation S440).

If the voltage setting operation for all bit lines connected to each of the memory cells connected to the first word line WL1 is not completed (No in operation S450), the control logic circuit 320 may repeat the above operation (operation S460).

When the voltage setting operation on all the bit lines connected to each of the memory cells connected to the first word line WL1 is completed (Yes in operation S450), the control logic circuit 320 may simultaneously perform the soft program operation on the memory cells connected to the second word line WL2 which is adjacent to the first word line WL1 and on which the program operation is performed after the first word line WL1, and the program operation on the memory cells connected to the first word line WL1 (operation S470).

The control logic circuit 320 may determine whether the soft program operation on the memory cells connected to the second word line WL2 is completed (operation S480). For example, if it is determined that the soft program operation on the memory cells connected to the second word line WL2 is not completed (No in operation S480), the soft program operation on the memory cells connected to the second word line WL2 and the program operation on the memory cells connected to the first word line WL1 may be continuously performed (operation S470). For example, if it is determined that the soft program operation on the memory cells connected to the second word line WL2 is completed (Yes in operation S480), only the program operation on the memory cells connected to the first word line WL1 may be continuously performed (operation S490).

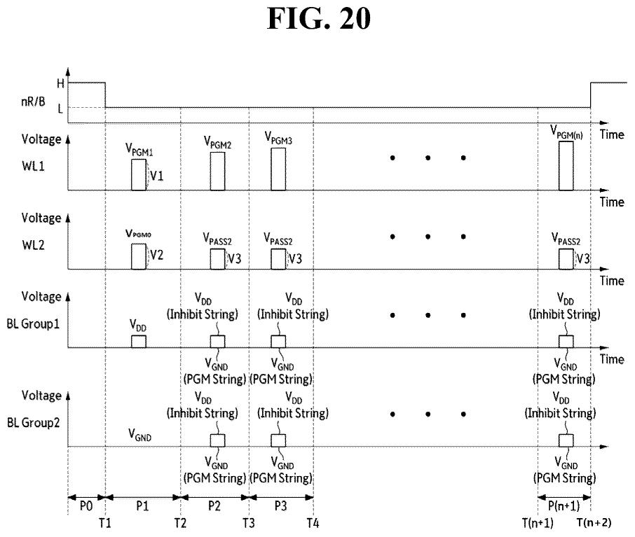

FIG. 20 is a diagram of the program operation of the memory device according to the method of FIG. 19, according to some embodiments.

Referring to FIG. 20, during the time interval from time point T1 to time point T(n+2), the first memory device 300A may perform the program operation on the first memory cells MC11 to MC1n connected to the first word line WL1 and perform the soft program operation on the second memory cells MC21 to MC2n connected to the second word line WL2, in response to the program command and the soft program command from the memory controller 200.

During the time interval P1, the soft program operation on the second memory cells MC21 to MC2n connected to the second word line WL2 and the program operation on the first memory cells MC11 to MC1n connected to the first word line WL1 may be performed simultaneously. When the soft program operation on the second memory cells MC21 to MC2n connected to the second word line WL2 is completed, only the program operation on the first memory cells MC11 to MC1n connected to the first word line WL1 may be performed from time point T2. As a result, the time interval for applying the program voltage to the first word line WL1 which is the selected word line may overlap the time interval for applying the soft program voltage to the second word line WL2 which is the adjacent word line.

During the time interval P1, the program voltage V_{PGM1} may be applied to the first word line WL1, and the soft program voltage V_{PGM0} may be applied to the second word line WL2. For example, the magnitude V2 of the soft program voltage V_{PGM0} may be smaller than the magnitude V1 of the program voltage V_{PGM1} applied to the first word line WL1, and may be larger than the magnitude V3 of the pass voltage V_{PASS2} applied to the second word line WL2 after the time point T2 (e.g., V1>V2>V3).

As a result, the magnitude of the soft program voltage at the time of the soft program operation for removing the deeply erased cells of the memory cells before performing the program operation on the memory cells may be smaller than the magnitude of the program voltage at the time of the program operation for writing data to the memory cells. For example, in FIG. 20, the magnitude of the soft program voltage V_{PGM0} applied to the second word line WL2 may be smaller than the magnitude of the program voltage to be applied to the second word line WL2 to write data to the memory cells connected to the second word line WL2.

The bit lines that constitute the memory cell array may be divided into a second bit line group (e.g., BL Group2) or a first bit line group (e.g., BL Group1) depending on whether the first voltage V_{GND} or the second voltage V_{DD} is applied. The second voltage V_{DD} may be applied to the bit lines included in the first bit line group (e.g., BL Group1), and the first voltage V_{GND} smaller the second voltage V_{DD} may be applied to the bit lines included in the second bit line group (e.g., BL Group2).

The bit lines included in the first bit line group (e.g., BL Group1) may be connected to the memory cells in which the upper data is to be programmed during the time interval P2 to the time interval P(n+1), among the first memory cells MC11 to MC1n connected to the first word line WL1. Alternatively, the bit lines included in the first bit line group (e.g., BL Group1) may be connected to the memory cells in which data is retained in the erased status without being programmed during the time interval P2 to the time interval P(n+1), among the first memory cells MC11 to MC1n connected to the first word line WL1.

That is, the program operation on the first memory cells MC11 to MC1n connected to the first word line WL1 and the soft program operation on the second memory cells MC21 to MC2n connected to the second word line WL2 may partially overlap each other in time. Accordingly, the second voltage V_{DD}, greater than the first voltage V_{GND} may need to be applied to the bit lines connected to the memory cells that are retained in the erased status without being programmed, among the first memory cells MC11 to MC1n connected to the first word line WL1.

The bit lines included in the second bit line group (e.g., BL Group2) may be connected to the memory cells in which the lower data is to be programmed during time intervals P2 to P(n+1), among the first memory cells MC11 to MC1n connected to the first word line WL1.

When performing the program operation on the first word line WL1, the program voltage applied to the first word line WL1 may be determined according to the ISPP method.

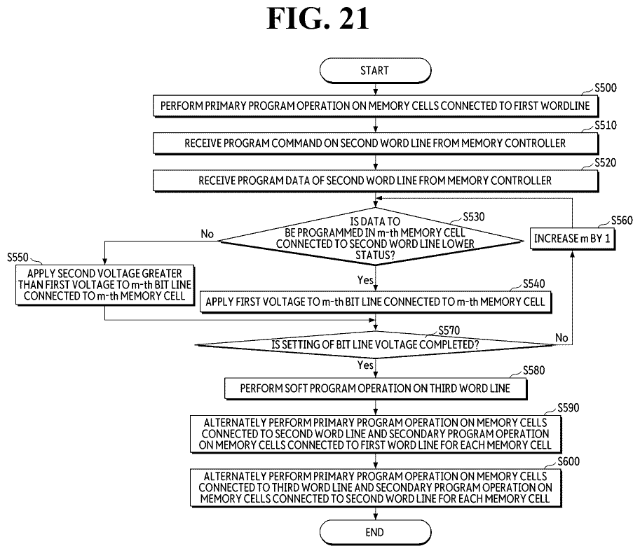

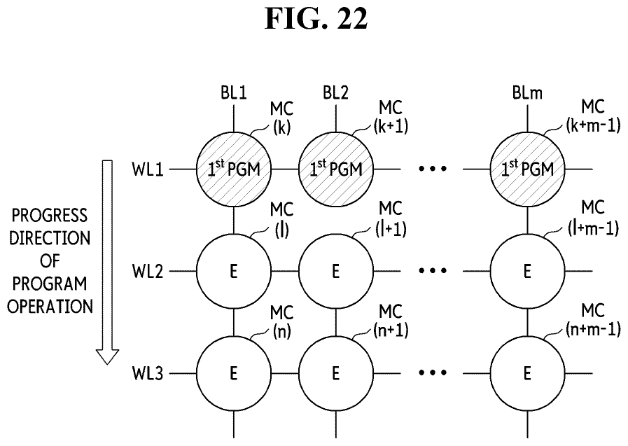

FIG. 21 is a flowchart of the operation of the memory device, according to some embodiments. FIGS. 22 to 27 are diagrams of the program operation on the memory cells connected to the selected word line and the soft program operation on the memory cells connected to adjacent word lines of the memory device, according to some embodiments.

In the following description, a case where the memory cells included in the memory cell array are quadruple level cells (QLC) that may store four (4) data bits is described as an example.

Referring to FIGS. 21 and 22 together, the memory cell array 330 may include first to third word lines WL1 to WL3, and first to m-th bit lines BL1 to BLm. A plurality of memory cells MC(k) to MC(k+m−1) may be formed in the region in which the first word line WL1 intersects each of the first to m-th bit lines BL1 to BLm (where k is a positive integer greater than one (1)). A plurality of memory cells MC(l) to MC(l+m−1) may be formed in the region in which the second word line WL2 intersects each of the first to m-th bit lines BL1 to BLm (where 1 is a positive integer greater than one (1)). A plurality of memory cells MC(n) to MC(n+m−1) may be formed in the region in which the third word line WL3 intersects each of the first to m-th bit lines BL1 to BLm. FIG. 22 shows only a part of the memory cell array 330, and the memory cell array 330 may include four (4) or more word lines.

The program operation on the memory cell array 330 may be performed in the order of the first word line WL1, the second word line WL2, and the third word line WL3. First, a primary program operation may be performed on the memory cells MC(k) to MC(k+m−1) connected to the first word line WL1 (operation S500). Subsequently, the first memory device 300A may receive the program command on the second word line WL2 and data to be programmed in the memory cells MC(l) to MC(l+m−1) connected to the second word line WL2 from the memory controller 200 (operations S510 and S520).

The control logic circuit 320 may determine whether the data to be programmed is in a lower status for each of the memory cells MC(l) to MC(l+m−1) connected to the second word line WL2 (operation S530). For example, if the data to be programmed in the memory cell MC(l) is determined to be in the lower status (Yes in operation S530), the control logic circuit 320 may apply a first voltage to the first bit line BL1 connected to the memory cell MC(l) (operation S540). If the data to be programmed in the memory cell MC(l) is determined not to be in the lower status (No in operation S530), the control logic circuit 320 may apply a second voltage greater than the first voltage to the first bit line BL1 connected to the memory cell MC(l) (operation S550).

When the voltage setting operation on all the bit lines BL1 to BLm connected to each of the memory cells MC(l) to MC(l+m−1) connected to the second word line WL2 is not completed (No in operation S570), the control logic circuit 320 may repeat the above operation (operation S560). For example, when the voltage setting for the first bit line BL1 is completed, the control logic circuit 320 may then determine whether the data to be programmed in the memory cell MC(l+1) is in the lower status (operation S530).

For example, if the data to be programmed in the memory cell MC(l+1) is determined to be in the lower status (Yes in operation S530), the control logic circuit 320 may apply the first voltage to the second bit line BL2 connected to the memory cell MC(l+1). If the data to be programmed in the memory cell MC(l+1) is determined not to be in the lower status (No in operation S530), the control logic circuit 320 may apply the second voltage greater than the first voltage to the second bit line BL2 connected to the memory cell MC(l+1) (operation S550).

As a result, the control logic circuit 320 may apply the first voltage or the second voltage to the bit lines BL1 to BLm, on the basis of the data to be programmed in the memory cells MC(l) to MC(l+m−1) connected to the second word line WL2, until the voltage setting for all the bit lines BL1 to BLm included in the memory cell array 330 is completed.

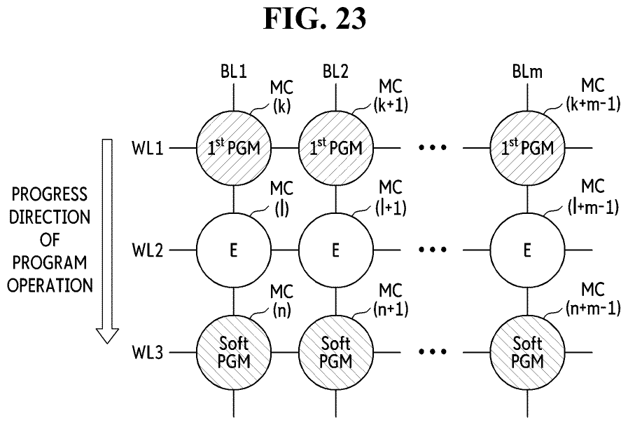

Referring to FIGS. 21 and 23, when the voltage setting operation for all the bit lines BL1 to BLm connected to each of the memory cells MC(l) to MC(l+m−1) connected to the second word line WL2 is completed (Yes in operation S570), the control logic circuit 320 may perform the soft program operation on the memory cells MC(n) to MC(n+m−1) connected to the third word line WL3 which is adjacent to the second word line WL2 and on which the program operation is to be performed following the second word line WL2 (operation S580).

That is, the control logic circuit 320 may apply the soft program voltage to the third word line WL3 in the state of completing the voltage setting for the bit lines BL1 to BLm on the basis of data to be programmed in the memory cells MC(l) to MC(l+m−1) connected to the second word line WL2.

Referring to FIGS. 21 and 24 to 26, the control logic circuit 320 may alternately perform the primary program operation on the memory cells MC(l) to MC(l+m−1) connected to the second word line WL2 and the secondary program operation on the memory cells MC(k) to MC(k+m−1) connected to the first word line WL1 for each memory cell (operation S590).

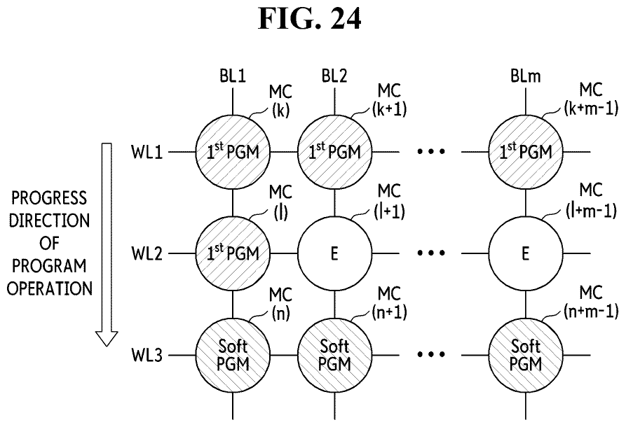

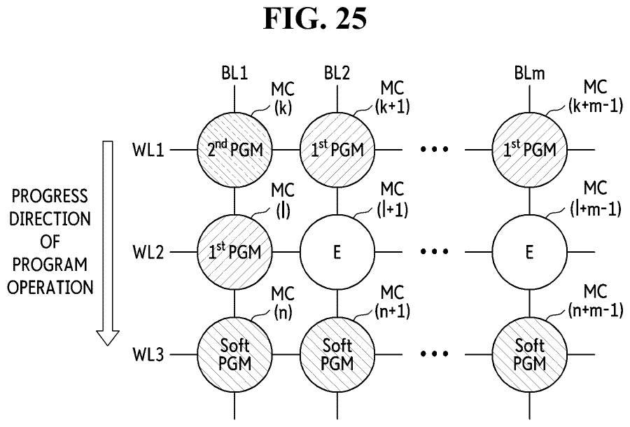

For example, referring to FIG. 24, the control logic circuit 320 may perform the primary program operation on the memory cell MC(l) formed in the region in which the second word line WL2 and the first bit line BL1 intersect in a status in which the soft program operation on the memory cells MC(n) to MC(n+m−1) connected to the third word line WL3 is completed. Referring to FIG. 25, the control logic circuit 320 may perform the secondary program operation on the memory cell MC(k) formed in the region in which the first word line WL1 and the first bit line BL1 intersect.

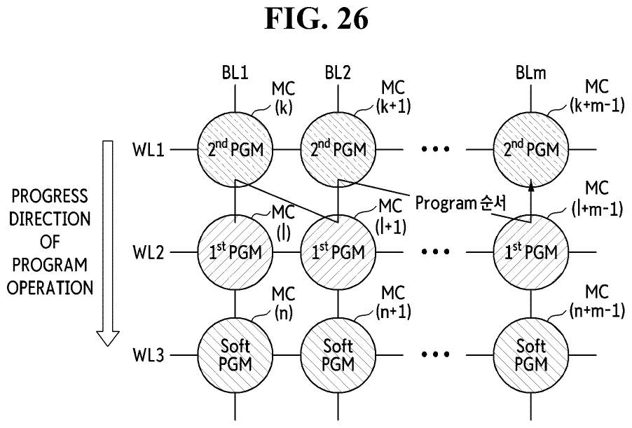

Referring to FIG. 26, the control logic circuit 320 may sequentially perform the primary program operation on the memory cell MC(l) formed in the region in which the second word line WL2 and the second bit line BL2 intersect, and the secondary program operation on the memory cell MC(k+1) formed in the region in which the first word line WL1 and the second bit line BL2 intersect. As a result, the program operation may be continuously performed until the primary program operation on the memory cells MC(l) to MC(l+m−1) connected to the second word line WL2 and the secondary program operation on the memory cells MC(k) to MC(k+m−1) connected to the first word line WL1 are completed.

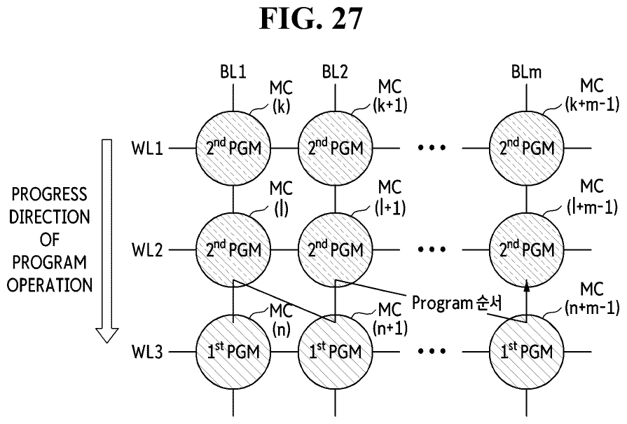

Referring to FIGS. 21 and 27 together, the control logic circuit 320 may alternately perform the primary program operation on the memory cells MC(n) to MC(n+m−1) connected to the third word line WL3, and the secondary program operation on the memory cells MC(l) to MC(l+m−1) connected to the second word line WL2 for each memory cell (operation S600).

For example, the control logic circuit 320 may perform the primary program operation on the memory cell MC(n) formed in the region in which the third word line WL3 and the first bit line BL1 intersect in the state in which the secondary program operation on the memory cells MC(k) to MC(k+m−1) connected to the first word line WL1 is completed. The control logic circuit 320 may perform the secondary program operation on the memory cell MC(l) formed in the region in which the second word line WL2 and the first bit line BL1 intersect.

The control logic circuit 320 may perform the primary program operation on the memory cell MC(n+1) formed in the region in which the third word line WL3 and the second bit line BL2 intersect. Then, the control logic circuit 320 may perform the secondary program operation on the memory cell MC(l+1) formed in the region in which the second word line WL2 and the second bit line BL2 intersect.

As a result, the program operation may be continuously performed, until the primary program operation on the memory cells MC(k) to MC(k+m−1) connected to the third word line WL3 and the secondary program operation on the memory cells MC(l) to MC(l+m−1) connected to the second word line WL2 are completed.

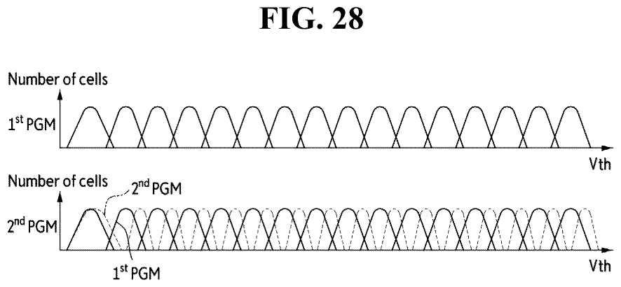

FIG. 28 is a diagram showing the threshold voltage distribution of the memory cells when the program operation on the memory cells is performed according to the method of FIG. 21.

In FIG. 28, an upper graph shows a threshold voltage distribution of the memory cells when data is primarily programmed in the memory cells in the case where the memory cells included in the memory cell array are QLC, and a lower graph shows a threshold voltage distribution of the memory cells when data is secondarily programmed in the memory cells.

As shown in FIG. 28, if data is programmed twice via the primary program and the secondary program when the memory cells are QLC, the threshold voltage distribution degradation phenomenon (disturbance) of the memory cells that occurs when data is primarily programmed may be alleviated.

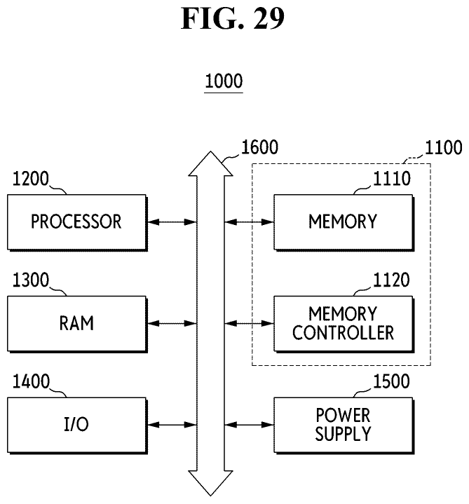

FIG. 29 is a diagram of a computing system including the storage device, according to some embodiments.

Referring to FIG. 29, a computing system 1000 may include a storage device 1100, a processor 1200, a random access memory (RAM) 1300, an input/output (I/O) device 1400, and a power supply device 1500. The storage device 1100 may include a memory device 1110 and a memory controller 1120. The plurality of memory devices 300 and the memory controller 200 shown in FIGS. 1 to 4 may be applied to the memory device 1110 and the memory controller 1120.

A computing system 3000 may further include ports that are capable of communicating with a video card, a sound card, a memory card, a universal serial bus (USB) device, or the like, or capable of communicating with other electronic devices. The computing system 3000 may be implemented as a personal computer, or may be implemented as a portable electronic device such as, but not limited to, a notebook computer, a mobile phone, a personal digital assistant (PDA), a camera, or the like.

The processor 1200 may perform particular calculations or tasks. According to an embodiment, the processor 1200 may be a micro-processor or a central processing unit (CPU). The processor 1200 may communicate with the RAM 1300, the input/output device 1400, and the storage device 1100 through a bus 1600, such as, but not limited to, an address bus, a control bus, and a data bus. According to an embodiment, the processor 1200 may also be connected to an expansion bus, such as a peripheral component interconnect (PCI) bus.

The RAM 1300 may store data required for the operation of the computing system 3000. For example, the RAM 1300 may be implemented as a dynamic RAM (DRAM), a mobile DRAM, a static RAM (SRAM), a PRAM, an FRAM, an RRAM, an MRAM, or the like.

The input/output device 1400 may include input means such as, but not limited to, a keyboard, a keypad, and a mouse, and/or output means such as, but not limited to, a printer and a display. The power supply device 1500 may provide the operating voltage required for the operation of the computing system 3000.

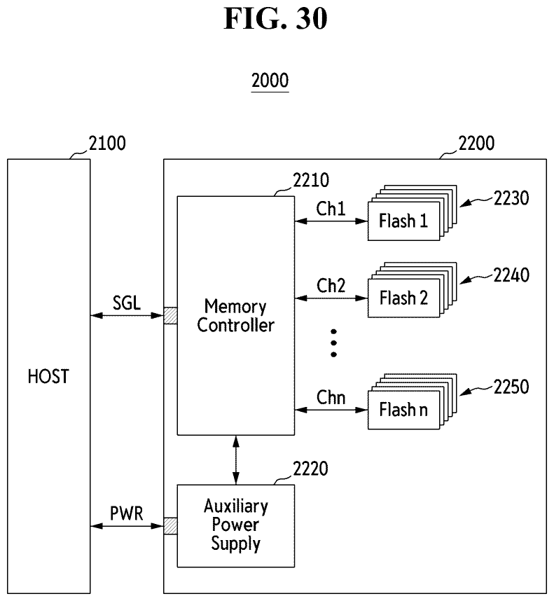

FIG. 30 is a diagram showing an example in which the storage device according to some embodiments is applied to an SSD system.

Referring to FIG. 30, an SSD system 2000 may include a host 2100 and an SSD 2200. The host 20 and the storage device 100 shown in FIG. 1 may be applied to the host 2100 and the SSD 2200. The SSD 2200 may send and receive signals to and from the host 2100 through a signal connector (SGL), and may receive input of power through a power connector (PWR). The SSD 2200 may include a memory controller 2210, an auxiliary power supply device 2220, and a plurality of memory devices (e.g., a first flash memory 2230, a second flash memory 2240, and a third flash memory 2250). The memory controller 200 and the plurality of memory devices 300 shown in FIGS. 1 to 4 may be applied to the memory controller 2210 and the plurality of memory devices 2230 to 2250.

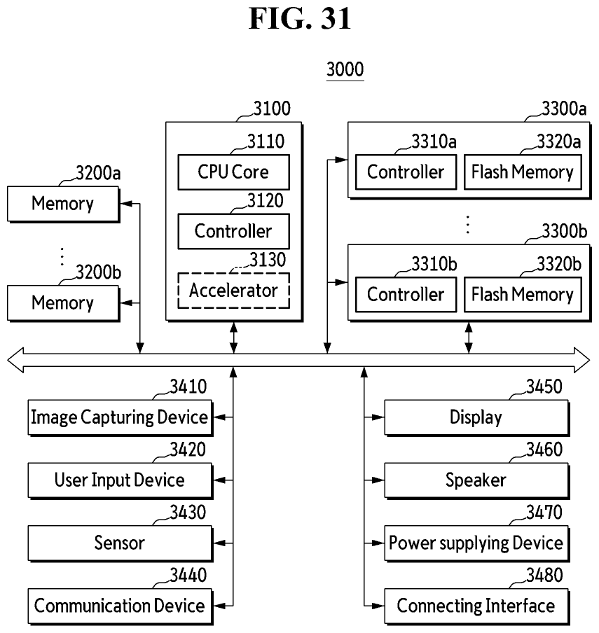

FIG. 31 is a diagram of a system including the memory device, according to some embodiments.

Referring to FIG. 31, the system 3000 may be and/or may include a mobile system such as, but not limited to, a mobile phone, a smart phone, a personal computer (PC), a tablet computer, a wearable device, a healthcare device, or an IoT (Internet of Things) device. However, the system 3000 of FIG. 31 is not necessarily limited to a mobile system, and may be a personal computer, a laptop computer, a server, a media player, or an automotive device such as, but not limited to, a navigation device.

Referring to FIG. 31, the system 3000 may include a main processor 3100, first and second memories 3200a and 3200b, and first and second storage devices 3300a and 3300b, and may further include one or more of an image capturing device 3410, a user input device 3420, a sensor 3430, a communication device 3440, a display 3450, a speaker 3460, a power supplying device 3470, and a connecting interface 3480. The storage device 100 shown in FIGS. 1 to 4 may be applied to the first and second storage devices 3300a and 3300b.

The main processor 3100 may control the overall operation of the system 3000, in particular, the operation of other components constituting the system 3000. Such a main processor 3100 may be implemented as a general-purpose processor, a dedicated processor, an application processor, or the like.

The main processor 3100 may include one or more CPU cores 3110, and may further include a controller 3120 for controlling the first and second memories 3200a and 3200b and/or the storage devices first and second 3300a and 3300b. According to an embodiment, the main processor 3100 may further include an accelerator block 3130, which may be and/or may include a dedicated circuit for high-speed data calculation such as, but not limited to, artificial intelligence (AI) data calculation. In an embodiment, the accelerator block 3130 may include, but not limited to, a graphics processing unit (GPU), a neural processing unit (NPU), and/or a data processing unit (DPU), and may also be implemented as an independent separate chip that may be physically independent of other components of the main processor 3100.

The first and second memories 3200a and 3200b may be used as a main storage device of the system 3000, and may include a volatile memory such as, but not limited to, a SRAM and/or a DRAM. Alternatively or additionally, the first and second memories 3200a and 3200b may also include a nonvolatile memory such as, but not limited, a flash memory, a PRAM, a RRAM, or the like. The first and second memories 3200a and 3200b may also be implemented in the same package as the main processor 3100.

The first and second storage devices 3300a and 3300b may function as nonvolatile storage devices that may store data regardless of the supply of power, and may have a relatively large storage capacity compared to the first and second memories 3200a and 3200b. The first and second storage devices 3300a and 3300b may include first and second controllers 3310a and 3310b and first and second nonvolatile storage devices 3320a and 3320b that may store data under the control of the first and second controllers 3310a and 3310b. The first and second nonvolatile storage devices 3320a and 3320b may include a V-NAND flash memory of a 2D structure or a 3D structure, but may also include other types of nonvolatile memory such as, but not limited to, a PRAM, a RRAM, or the like.

The first and second storage devices 3300a and 3300b may be included in the system 3000 in a status of being physically separated from the main processor 3100, or may be implemented in the same package as the main processor 3100. Furthermore, the first and second storage devices 3300a and 3300b may be detachably coupled to other components of the system 3000 through an interface such as a connecting interface 3480 as described below, by having a form such as a memory card. The first and second storage devices 3300a and 3300b may be devices to which a standard protocol such as universal flash storage (UFS) may be applied, but are not necessarily limited thereto.

The image capturing device 3410 may capture still images or moving images, and may be and/or may include a camera, a camcorder, a webcam, or the like.

The user input device 3420 may receive various types of data that may be input from a user of the system 3000, and may be and/or may include, but not be limited to, a touch pad, a keypad, a keyboard, a mouse, a microphone, or the like.

The sensor 3430 may sense various types of physical quantities that may be acquired from outside the system 3000 and convert the sensed physical quantities into electrical signals. Such a sensor 3430 may be and/or may include, but not be limited to, a temperature sensor, a pressure sensor, an illuminance sensor, a position sensor, an acceleration sensor, a biosensor, a gyroscope, or the like.

The communication device 3440 may transmit and/or receive signals to and/or from other devices outside the system 3000 in accordance with various communication protocols. Such a communication device 3440 may be implemented to include, for example, an antenna, a transceiver, a modem, or the like.

The display 3450 and the speaker 3460 may function as output devices that may output visual information and/or audible information to a user of the system 3000.

The power supplying device 3470 may appropriately convert power supplied from a battery equipped in the system 3000 and/or an external power source, and supply the converted power to each component of the system 3000.

The connecting interface 3480 may provide a connection between the system 3000 and an external device connected to the system 3000 and may be capable of sending and/or receiving data to and/or from the system 1000. The connecting interface 3480 may be implemented in various interface types, such as, but not limited to, an advanced technology attachment (ATA) interface, a serial ATA (SATA) interface, an external SATA (e-SATA) interface, a small computer small interface (SCSI), a serial-attached SCSI (SAS), a peripheral component interconnection (PCI) interface, a PCI express (PCIe) interface, a non-volatile memory (NVM) express (NVMe) interface, an Institute of Electrical and Electronics Engineers (IEEE) 1394 (Fire Wire) interface, a universal serial bus (USB) interface, a secure digital (SD) card interface, a multi-media card (MMC) interface, an embedded MMC (eMMC) interface, a universal flash storage (UFS) interface, an embedded UFS (eUFS) interface, a compact flash (CF) card interface, or the like.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it is to be appreciated that the embodiments as described above are not restrictive but illustrative in all respects.

What is claimed is:

1. A memory device, comprising:
a memory cell array comprising a plurality of memory cells coupled with a plurality of word lines and a plurality of bit lines;
a row decoder circuit configured to select at least one of the plurality of word lines based on a row address;
a voltage generation circuit configured to:
provide a first word line voltage to a selected word line from among the plurality of word lines; and
provide a second word line voltage to an unselected word line from among the plurality of word lines;
a page buffer circuit coupled with the plurality of bit lines, and configured to:
receive first data to be programmed in the plurality of memory cells;
provide a first bit line voltage to a selected bit line from among the plurality of bit lines; and
provide a second bit line voltage to an unselected bit line from among the plurality of bit lines; and
a control logic circuit configured to control the row decoder circuit, the voltage generation circuit, and the page buffer circuit,
wherein the second bit line voltage is greater than the first bit line voltage,
wherein the plurality of word lines comprises a first word line and a second word line that are sequentially selected by the row decoder circuit,
wherein the plurality of memory cells comprises a first memory cell coupled with the first word line, and a second memory cell coupled with the second word line,
wherein the first memory cell and the second memory cell share a first bit line, and
wherein the control logic circuit is further configured to:
apply the first bit line voltage to the first bit line, based on second data to be programmed in the first memory cell being in a lower status; and
apply a first program voltage to the second word line, while applying the first bit line voltage to the first bit line.

2. The memory device of claim 1, wherein the plurality of memory cells further comprises a third memory cell coupled with the first word line,
wherein the third memory cell is different from the first memory cell, and
wherein the control logic circuit is further configured to:
apply the second bit line voltage to a second bit line coupled with the third memory cell, based on the second data to be programmed in the first memory cell being in the lower status and third data to be programmed in the third memory cell being in an upper status.

3. The memory device of claim 2, wherein the control logic circuit is further configured to:
apply the first program voltage to the second word line while applying the second bit line voltage to the second bit line.

4. The memory device of claim 1, wherein the control logic circuit is further configured to:
apply the first program voltage to the second word line; and
apply a second program voltage different from the first program voltage to the first word line.

5. The memory device of claim 4, wherein the control logic circuit is further configured to:
apply the second program voltage to the first word line; and
apply a third program voltage to the second word line, and
wherein a magnitude of the third program voltage is greater than a magnitude of the first program voltage.

6. The memory device of claim 1, wherein the plurality of memory cells further comprises a third memory cell that is coupled with the first word line and is different from the first memory cell,
wherein the control logic circuit is further configured to:
apply the first bit line voltage to a second bit line coupled with the third memory cell based on third data not being programmed in the third memory cell, and
apply the first program voltage to the second word line, while applying the first bit line voltage to the second bit line.

7. The memory device of claim 6, wherein a first time interval during which the control logic circuit applies the first program voltage to the second word line does not overlap with a second time interval during which the control logic circuit applies a second program voltage to the first word line by incremental step pulse programming (ISPP).

8. The memory device of claim 1, wherein the plurality of memory cells further comprises a third memory cell coupled with the first word line and different from the first memory cell,
wherein the control logic circuit is further configured to:
apply the second bit line voltage to a second bit line coupled with the third memory cell, based on third data not being programmed in the third memory cell, and
apply the first program voltage to the second word line, while applying the second bit line voltage to the second bit line.

9. The memory device of claim 8, wherein a first time interval during which the control logic circuit applies the first program voltage to the second word line at least partially overlaps with a second time interval during which the control logic circuit applies a second program voltage to the first word line by incremental step pulse programming (ISPP).

10. A memory device, comprising:
a memory cell array comprising a plurality of memory cells coupled with a plurality of word lines and a plurality of bit lines;
a row decoder circuit configured to select at least one of the plurality of word lines based on a row address;
a voltage generation circuit configured to:
provide a first word line voltage to a selected word line from among the plurality of word lines; and
provide a second word line voltage to an unselected word line from among the plurality of word lines;
a page buffer circuit coupled with the plurality of bit lines, and configured to:
receive first data to be programmed in the plurality of memory cells;
provide a first bit line voltage to a selected bit line from among the plurality of bit lines; and
provide a second bit line voltage to an unselected bit line from among the plurality of bit lines; and
a control logic circuit configured to control the row decoder circuit, the voltage generation circuit, and the page buffer circuit,
wherein the second bit line voltage is greater than the first bit line voltage,
wherein the plurality of word lines comprises a first word line, a second word line and a third word line that are sequentially selected by the row decoder circuit,
wherein the plurality of memory cells comprises a first memory cell coupled with the first word line, a second memory cell coupled with the second word line, and a third memory cell coupled with the third word line,
wherein the first memory cell, the second memory cell, and the third memory cell share a first bit line,
wherein the control logic circuit is further configured to:
apply the first bit line voltage to the first bit line based on second data to be programmed in the second memory cell being in a lower status, wherein the second data to be programmed in the second memory cell is programmed into the second memory cell after the control logic circuit performs a primary program operation, and
apply a first program voltage to the third word line while applying the first bit line voltage to the first bit line.

11. The memory device of claim 10, wherein the control logic circuit is further configured to:
apply the first program voltage to the third word line to perform a soft program operation on the third memory cell; and
apply a second program voltage different from the first program voltage to the second word line to perform the primary program operation on the second memory cell.

12. The memory device of claim 11, wherein the control logic circuit is further configured to:
perform a secondary program operation on the first memory cell, after the performing of the primary program operation on the second memory cell.

13. The memory device of claim 12, wherein the control logic circuit is further configured to:
apply a third program voltage to the third word line to perform the primary program operation on the third memory cell, after performing the secondary program operation on the first memory cell, and
wherein a magnitude of the third program voltage is greater than a magnitude of the first program voltage.

14. The memory device of claim 10, wherein a first time interval during which the control logic circuit applies a second program voltage different from the first program voltage to the second word line at least partially overlaps with a second time interval during which the control logic circuit applies the first program voltage to the third word line.

15. A method for operating a memory device, the method comprising:
receiving, from a memory controller, a program command;
selecting, by a row decoder circuit of the memory device, a first word line from among a plurality of word lines;
receiving, from the memory controller, first data to be programmed into a first memory cell coupled with the first word line;
applying, by a control logic circuit of the memory device, a first voltage to a first bit line coupled with the first memory cell based on the first data to be programmed in the first memory cell being in a lower status; and
applying, by the control logic circuit, a first program voltage to a second word line to be selected by the row decoder circuit following the first word line by the control logic circuit, in a first state in which the first voltage is applied to the first bit line during a first time interval.

16. The method for operating the memory device of claim 15, further comprising:
applying, by the control logic circuit, a second voltage to a second bit line coupled with a second memory cell based on second data to be programmed into the second memory cell being in an upper state, the second voltage being greater than the first voltage, the second memory cell being coupled with the first word line and being different from the first memory cell; and
applying, by the control logic circuit, the first program voltage to the second word line, in a second state in which the second voltage is applied to the second bit line during the first time interval.

17. The method for operating the memory device of claim 15, further comprising:
applying, by the control logic circuit, a second program voltage different from the first program voltage to the first word line during a second time interval after the first time interval; and
programming the first memory cell by applying the second program voltage.

18. The method for operating the memory device of claim 15, further comprising:
performing, by the control logic circuit, a soft program operation on a second memory cell coupled with the second word line and the first bit line by applying the first program voltage to the second word line during the first time interval; and
simultaneously programming, by the control logic circuit, the first memory cell by applying a second program voltage different from the first program voltage to the first word line.

19. The method for operating the memory device of claim 18, further comprising:
receiving, from the memory controller, second data to be programmed to the second memory cell coupled with the second word line;
applying, by the control logic circuit, the first voltage to the first bit line based on the second data to be programmed in the second memory cell being in the lower status, after a primary program operation is performed on the first memory cell and before the primary program operation is performed on the second memory cell; and
applying, by the control logic circuit, a third program voltage to a third word line in the first state in which the first voltage is applied to the first bit line.

20. The method for operating the memory device of claim 19, further comprising:
performing, by the control logic circuit, a secondary program operation on the first memory cell, after performing the primary program operation on the second memory cell.
